(19) United States
(12) Patent Application Publication
(10) Pub. No.: US 2025/0044090 A1
(43) Pub. Date: Feb. 6, 2025

(54) CIRCUIT DEVICE AND PHYSICAL QUANTITY DETECTION DEVICE

(71) Applicant: SEIKO EPSON CORPORATION, Tokyo (JP)

(72) Inventors: Tomoaki Takahashi, Minowa-machi (JP); Noriyuki Murashima, Chino-shi (JP)

(21) Appl. No.: 18/787,221

(22) Filed: Jul. 29, 2024

(30) Foreign Application Priority Data
Jul. 31, 2023 (JP) 2023-124196

(51) Int. Cl. G01C 19/5649

(52) U.S. Cl. CPC G01C 19/5649

(57) ABSTRACT

A circuit device includes a drive circuit that drives a physical quantity transducer, a detection circuit that detects a physical quantity based on a detection signal from the physical quantity transducer to output detection data of the physical quantity, a DSP that performs a digital signal process including a digital filtering process on the detection data, a storage unit that stores a program in which a plurality of instructions is written, and a CPU that operates based on the program and performs at least one of a temperature correction operation of the detection data and a failure diagnosis.

The present application is based on, and claims priority from JP Application Serial Number 2023-124196, filed Jul. 31, 2023, the disclosure of which is hereby incorporated by reference herein in its entirety.

### BACKGROUND

### 1. Technical Field

The present disclosure relates to circuit device, a physical quantity detection device, and the like.

### 2. Related Art

JP-A-2020-153891 discloses a sensor failure prediction system that detects in advance the state leading to a failure of a physical quantity sensor by a processor generating prediction information about a stepwise or continuous state leading to the failure of the physical quantity sensor based on signal information and reference information about the measured value of a drive signal or a detection signal.

However, in the related art disclosed in JP-A-2020-153891, it was not clear how the failure prediction information and the detection signal of the physical quantity are specifically generated by the processor having what configuration.

### SUMMARY

According to an aspect of the present disclosure, a circuit device includes a drive circuit that drives a physical quantity transducer, a detection circuit that detects a physical quantity based on a detection signal from the physical quantity transducer to output detection data of the physical quantity, a DSP that performs a digital signal process including a digital filtering process on the detection data, a storage unit that stores a program in which a plurality of instructions is written, and a CPU that operates based on the program and performs at least one of a temperature correction operation of the detection data and a failure diagnosis.

Another aspect of the present disclosure relates to a physical quantity detection device including the circuit device described above and the physical quantity transducer.

### BRIEF DESCRIPTION OF THE DRAWINGS

FIG. 1 shows a configuration example of a circuit device and a physical quantity detection device according to the present embodiment.

FIG. 2 is a detailed configuration example of the circuit device and the physical quantity detection device according to the present embodiment.

FIG. 3 shows a configuration example of a failure detection circuit.

FIG. 4 is an example of a physical quantity transducer.

FIG. 5 is a signal waveform diagram illustrating the operation of the present embodiment.

FIG. 6 is a signal waveform diagram illustrating the operation of the present embodiment.

FIG. 7 is an explanatory diagram of the angular velocity dependence of failure diagnosis results in the present embodiment.

FIG. 8 is a block diagram showing a detailed configuration example of a DSP and a CPU.

FIG. 9 shows an example of the hardware configuration of the CPU.

FIG. 10 is a signal waveform diagram illustrating the operation of the CPU.

FIG. 11 is a state transition diagram describing the operation of the CPU.

FIG. 12 is an explanatory diagram of a cooperative operation between the DSP and the CPU.

FIG. 13 is an explanatory diagram of a DSP execution sequence.

FIG. 14 is an explanatory diagram of a low-pass filtering process.

FIG. 15 is an explanatory diagram of a notch filtering process.

FIG. 16 is an explanatory diagram of a user-defined filtering process.

FIG. 17 is an explanatory diagram of the operation of a CPU in a comparative example.

FIG. 18 is an explanatory diagram of noise generated due to the cycle of failure diagnosis.

FIG. 19 is an explanatory diagram of the operation of the DSP and CPU of the present embodiment.

FIG. 20 is an explanatory diagram of operation frequencies of the DSP and CPU.

### DESCRIPTION OF EMBODIMENTS

The present embodiment will be described below. Note that the present embodiment described below does not unduly limit the content described in the claims. Furthermore, not all of the configurations described in the present embodiment are essential configuration requirements.

### 1. Circuit Device, Physical Quantity Detection Device

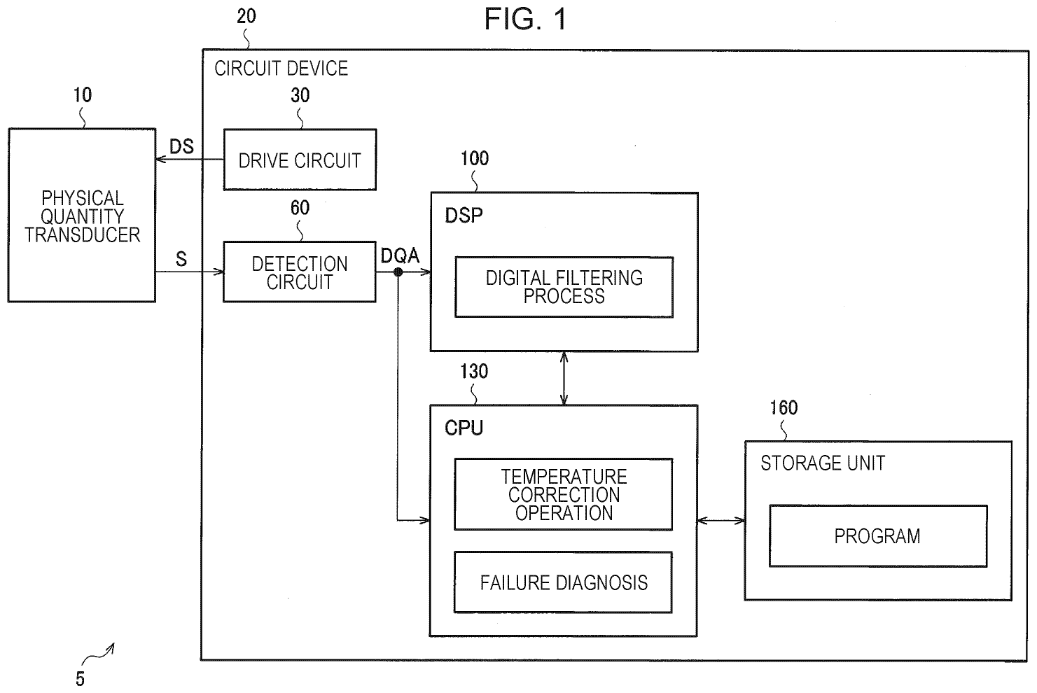

FIG. 1 shows a configuration example of a circuit device 20 and a physical quantity detection device 5 of the present embodiment. The physical quantity detection device 5, which is a sensor device, includes a physical quantity transducer 10 and the circuit device 20. The physical quantity detection device 5 can also be referred to as a physical quantity measuring device. Note that the circuit device 20 and the physical quantity detection device 5 are not limited to the configuration shown in FIG. 1, and various modifications such as omitting some of these components or adding other components are possible.

The physical quantity transducer 10 is an element for detecting a physical quantity, and is, for example, a vibrator. When the physical quantity transducer 10 is a vibrator, the physical quantity transducer 10 has a vibrating piece, and the physical quantity is detected using the vibration of the vibrating piece. For example, when the physical quantity transducer 10 is a gyro sensor element, angular velocity is detected as the physical quantity.

Examples of the gyro sensor element include a sensor element having a piezoelectric vibrating piece formed of a thin plate of piezoelectric material such as quartz and the like. Specifically, the gyro sensor element is a sensor element having a double T-shaped, tuning fork-shaped, or H-shaped vibrating piece formed of a quartz substrate such as a Z-cut. Alternatively, a micro electro mechanical systems (MEMS) type sensor element may be used as the gyro sensor element. Note that the physical quantity detected by the physical quantity transducer 10 may be a physical quantity other than angular velocity, such as an angular acceleration, an angle, an acceleration, a speed, a moving distance, or a pressure.

The circuit device 20 is, for example, a semiconductor circuit device, and is an integrated circuit device referred to as an integrated circuit (IC) as an example. The circuit device 20 can be referred to as a physical quantity detection circuit. In FIG. 1, the circuit device 20 includes a drive circuit 30, a detection circuit 60, a digital signal processor (DSP) 100, a central processing unit (CPU) 130, and a storage unit 160.

The drive circuit 30 is a circuit that drives the physical quantity transducer 10. For example, the drive circuit 30 drives the physical quantity transducer 10 by outputting a drive signal DS to the physical quantity transducer 10. For example, when the physical quantity transducer 10 has a vibrating piece, the drive signal DS from the drive circuit 30 drives the vibrating piece to vibrate. The drive signal DS is, for example, a rectangular wave signal, but may also be a sinusoidal wave signal. Taking the gyro sensor element as an example, the angular velocity is detected by driving the drive circuit 30 to vibrate the vibrating piece and detecting the Coriolis force.

The detection circuit 60 detects a physical quantity based on a detection signal S from the physical quantity transducer 10. For example, the detection circuit 60 detects a physical quantity based on the detection signal S to output detection data DQA of the physical quantity. The detection signal S is, for example, a detection signal of a physical quantity with the drive frequency of the drive signal DS as a carrier frequency. The detection circuit 60 detects a physical quantity in the detection signal S by, for example, synchronously detecting a signal based on the detection signal S using a synchronization signal. The detection data DQA output by the detection circuit 60 is digital data, and is, for example, data indicating the detection level of the detected physical quantity.

The DSP 100 is a processor that performs a digital signal process. The DSP 100 performs the digital signal process including a digital filtering process on the detection data DQA of the physical quantity from the detection circuit 60. Then, the detection data after a digital filtering process by the DSP 100 is output as, for example, the final physical quantity detection value of the physical quantity detection device 5. The digital filtering process that can be performed by the DSP 100 includes various filtering processes such as a low-pass filtering process, a notch filtering process, a high-pass filtering process, a bandpass filtering process, or a user-defined filtering process. Further, the digital signal process performed by the DSP 100 is not limited to the digital filtering process, but can include various digital signal processes such as a digital temperature compensation process and various correction processes. The DSP 100 is a digital signal processing circuit composed of a hardware circuit for performing various digital signal processes.

The storage unit 160 stores a program in which a plurality of instructions is written. The storage unit 160 is a storage circuit composed of a memory or a register circuit. A plurality of instructions executable by the CPU 130 is written in the program stored in the storage unit 160. The plurality of instructions is an instruction set. Such instructions include, for example, arithmetic operation instructions such as addition, subtraction, immediate addition, immediate subtraction, comparison and immediate comparison, shift operation instructions such as a right logical shift, a right arithmetic shift and a left logical shift, logical operation instructions such as AND, OR, XOR, and NOT, a transfer instruction between a register and an SRAM, and various conditional branch instructions. Note that the storage unit 160 may store information other than programs, for example, information such as filter coefficients necessary for the digital filtering process of the DSP 100. Furthermore, the storage unit 160 may be achieved by a volatile memory such as a RAM, a nonvolatile memory such as an EPROM, an EEPROM, or a ROM, or may be achieved by both the volatile memory and the nonvolatile memory.

The CPU 130 operates based on a program stored in the storage unit 160. For example, the CPU 130 decodes each of a plurality of instructions written in a program, and performs various arithmetic processes based on the decoding results. The CPU 130 thus operates based on the program in such a manner and performs at least one of the temperature correction operation of the detection data of the detection circuit 60 and the failure diagnosis. For example, the instructions written in the program are various instructions for executing such a temperature correction operation and a failure diagnosis. For example, the temperature correction operation is a process of calculating a temperature correction value for a temperature compensation process of detection data. For example, the temperature correction operation is a process of calculating a temperature correction value for zero point correction and a temperature correction value for sensitivity correction. The temperature compensation process is a process that suppresses and compensates for fluctuations in detection values of the physical quantity due to temperature fluctuations. The failure diagnosis is a diagnosis of an abnormal state of the circuit device 20 or the physical quantity detection device 5 including the circuit device 20. Examples of the failure diagnosis include a failure diagnosis using an electrostatic leakage component, which will be described later, a failure diagnosis using a mechanical leakage component, or a failure diagnosis of a computing unit such as the DSP 100 or the CPU 130. The CPU 130 may include a peripheral circuit in addition to the CPU core circuit. Examples of the peripheral circuit include a watchdog timer circuit, a clock counter, and a threshold value determination circuit.

The DSP 100 and the CPU 130 are prepared, for example, as macroblocks, and laid out in the circuit device 20, which is a semiconductor IC. For example, the macroblocks of the DSP 100 and the CPU 130 are also used in the circuit device 20 and the physical quantity detection device 5 of each of a plurality of types of products.

As described above, the circuit device 20 of the present embodiment includes the drive circuit 30 that drives the physical quantity transducer 10, the detection circuit 60 that detects the physical quantity based on the detection signal S from the physical quantity transducer 10, the DSP that performs a digital signal process on the detection data DQA of the detection circuit 60, and the CPU 130 that operates based on a program stored in the storage unit 160 and performs a temperature correction operation of the detection data and a failure diagnosis. In this way, the DSP 100 can perform a digital signal process including a digital filtering process on the detection data DQA of the physical quantity in the detection circuit 60 to obtain the detection value of the physical quantity. For example, use of the DSP 100 that is faster than the CPU 130 makes it possible to output the detection value of the physical quantity with higher throughput. On the other hand, the CPU 130 that operates according to a program stored in the storage unit 160 can perform the temperature correction operation or the failure diagnosis. The CPU 130 can perform the temperature correction operation or the failure diagnosis with a high degree of freedom, for example, using a rewritable program. That is, it is possible to achieve the circuit device 20 and the physical quantity detection device 5 that can share and perform the process of the physical quantity and the temperature correction operation or the failure diagnosis. Furthermore, the cooperative operation using the two computing units (DSP, CPU) can also be performed by exchanging data between the DSP 100 and the CPU 130.

### 2. Detailed Configuration Example

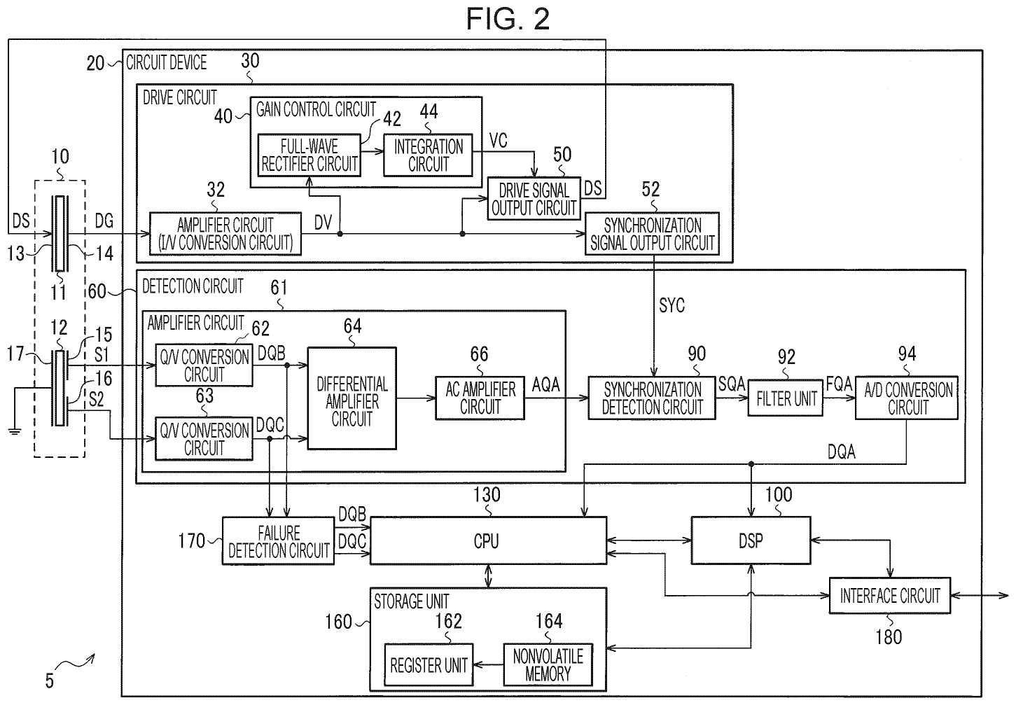

FIG. 2 shows a detailed configuration example of the circuit device 20 and physical quantity detection device 5 of the present embodiment. The circuit device 20 includes the drive circuit 30, the detection circuit 60, the DSP 100, the CPU 130, and the storage unit 160. Further, the circuit device 20 can include a failure detection circuit 170 and an interface circuit 180. Note that the circuit device 20 and the physical quantity detection device 5 are not limited to the configuration shown in FIG. 2, and various modifications such as omitting some of these components or adding other components are possible.

The physical quantity transducer 10, which is a sensor element, includes vibrating pieces 11 and 12, drive electrodes 13 and 14, detection electrodes 15 and 16, and a ground electrode 17. The vibrating pieces 11 and 12 are piezoelectric vibrating pieces each of which is formed of a thin plate of a piezoelectric material such as crystal, for example. Specifically, the vibrating pieces 11 and 12 are vibrating pieces each of which is formed of a Z-cut quartz substrate. Note that the piezoelectric material of the vibrating pieces 11 and 12 may be a material other than crystal, such as ceramics or silicon.

The drive signal DS from the drive circuit 30 is supplied to the drive electrode 13, thereby causing the driving vibrating piece 11 to vibrate. A feedback signal DG from the drive electrode 14 is then input to the drive circuit 30. For example, the feedback signal DG generated by the vibration of the vibrating piece 11 is input to the drive circuit 30. When the drive vibrating piece 11 vibrates, the detecting vibrating piece 12 vibrates, and charges generated by this vibration are input to the detection circuit 60 from the detection electrodes 15 and 16 as detection signals S1 and S2. Here, the ground electrode 17 is set to the GND, which is a ground potential. The circuit device 20 detects the physical quantity such as the angular velocity corresponding to the detection signals S1 and S2 based on these detection signals S1 and S2.

The drive circuit 30 includes an amplifier circuit 32, a gain control circuit 40, a drive signal output circuit 50, and a synchronization signal output circuit 52.

The amplifier circuit 32 amplifies the feedback signal DG from the physical quantity transducer 10. For example, the amplifier circuit 32, which is an I/V conversion circuit, converts the current feedback signal DG from the physical quantity transducer 10 into a voltage signal DV to output the voltage signal DV. The amplifier circuit 32 can be achieved by an arithmetic amplifier, a feedback resistance element, a feedback capacitor, and the like.

The gain control circuit 40 outputs a control voltage VC to the drive signal output circuit 50 to control the amplitude of the drive signal DS. Specifically, the gain control circuit 40, which is an AGC circuit, monitors the signal DV and controls the gain of the oscillation loop. For example, in the drive circuit 30, in order to keep the sensitivity of the sensor constant, it is necessary to keep the amplitude of the drive voltage supplied to the physical quantity transducer 10 constant. For this reason, the gain control circuit 40 for automatically adjusting the gain is provided in the oscillation loop of the drive vibration system. The gain control circuit 40 automatically adjusts the gain variably so that the amplitude of the feedback signal DG from the physical quantity transducer 10 is constant.

The gain control circuit 40 includes a full-wave rectifier circuit 42 and an integration circuit 44. The full-wave rectifier circuit 42 performs full-wave rectification of the alternating current signal DV output from the amplifier circuit 32. The integration circuit 44 performs the integration process on the signal from the full-wave rectifier circuit 42. Specifically, the integration circuit 44 performs an integration process on the signal full-wave rectified by the full-wave rectifier circuit 42 to output the control voltage VC obtained by the integration process to the drive signal output circuit 50. In this way, the control voltage VC corresponding to the DC voltage obtained by smoothing the full-wave rectified signal can be output to the drive signal output circuit 50.

The drive signal output circuit 50 outputs the drive signal DS based on the signal DV amplified by the amplifier circuit 32. The drive signal output circuit 50 outputs the rectangular wave drive signal DS such that, for example, the control voltage VC from the gain control circuit 40 is a high-level voltage that is a high potential side voltage. When the drive signal output circuit 50 outputs the rectangular wave drive signal DS in this way, the drive signal output circuit 50 can be achieved by a comparator or the like. Note that a modification is also possible in which the drive signal output circuit 50 outputs, for example, a sinusoidal wave drive signal DS.

The synchronization signal output circuit 52 outputs a synchronization signal SYC. The synchronization signal SYC is a signal based on the drive signal DS. For example, the synchronization signal SYC is a signal generated based on the drive signal DS. Specifically, the synchronization signal SYC is a signal corresponding to the drive signal DS, and is, for example, a clock signal with a first frequency that is a frequency same as that of the drive signal DS with the first frequency. For example, the synchronization signal SYC is a signal that is in phase with the drive signal DS. Here, the term “in phase” includes a case where the phases are substantially in phase. Specifically, in FIG. 2, the synchronization signal output circuit 52 generates the synchronization signal SYC based on the signal DV from the amplifier circuit 32. For example, as shown in FIG. 2, when the drive circuit 30 receives the feedback signal DG driven by the drive signal DS from the physical quantity transducer 10 and performs feedback control, the synchronization signal SYC is a signal generated based on this feedback signal DG. Specifically, the synchronization signal SYC is a signal generated based on the signal DV obtained by amplifying the feedback signal DG by the amplifier circuit 32. For example, the synchronization signal output circuit 52 outputs the synchronization signal SYC by shaping the sinusoidal wave signal DV into a rectangular wave signal using a comparator or the like. Alternatively, the synchronization signal SYC may be a signal generated by buffering the drive signal DS. The synchronization signal SYC can also be referred to as, for example, a reference signal or a detection clock signal.

The detection circuit 60 includes an amplifier circuit 61, a synchronization detection circuit 90, a filter unit 92, and an A/D conversion circuit 94.

The amplifier circuit 61 receives the detection signals S1 and S1 from the physical quantity transducer 10, and performs a charge-voltage conversion, a signal amplification, and a gain adjustment. The detection signals S1 and S2 constitute differential signals. The amplifier circuit 61 includes Q/V conversion circuits 62 and 63, a differential amplifier circuit 64, and an AC amplifier circuit 66.

The Q/V conversion circuits 62 and 63 convert the detection signals S1 and S2 that are charge signals from the physical quantity transducer 10 into voltage signals. Each of the Q/V conversion circuits 62 and 63 is a continuous charge-voltage conversion circuit having a feedback resistor.

The differential amplifier circuit 64 performs a differential amplification of the signals VS1 and VS2 from the Q/V conversion circuits 62 and 63. This achieves the amplification of the physical quantity signals included in the signals VS1 and VS2. That is, since the physical quantity signals included in the signals VS1 and VS2 are differential signals, the signals are amplified by the differential amplification. The AC amplifier circuit 66 amplifies the output signal of the differential amplifier circuit 64 to output the amplified output signal as an output signal AQA of the amplifier circuit 61. The AC amplifier circuit 66 performs, for example, a signal gain adjustment.

The synchronization detection circuit 90 performs synchronization detection on the output signal AQA of the amplifier circuit 61 based on the synchronization signal SYC. This makes it possible to extract the physical quantity signal that is the desired signal included in the output signal AQA, and detect the physical quantity.

For example, the detection signals S1 and S2, which are charge signals from the physical quantity transducer 10, are delayed in phase by 90 degrees with respect to the drive signal DS, which is a voltage signal. Further, the phase is delayed by 90 degrees in the Q/V conversion circuits 62, 63, and the like of the amplifier circuit 61. Therefore, the phase of the output signal AQA of the amplifier circuit 61 is delayed by 180 degrees with respect to the drive signal DS. Therefore, for example, by performing synchronization detection using the synchronization signal SYC that is in phase with the drive signal DS, it is possible to remove unnecessary signals whose phase is delayed by 90 degrees with respect to the drive signal DS, and detect the physical quantity.

The filter unit 92 performs a filtering process such as a low-pass filtering process on an output signal SQA of the synchronization detection circuit 90. The filter unit 92 functions as a pre-filter for the A/D conversion circuit 94 at the subsequent stage. The filter unit 92 also functions as a circuit that attenuates an unnecessary signal that cannot be removed by synchronization detection. The A/D conversion circuit 94 performs A/D conversion on an analog output signal FQA from the filter unit 92 to output digital detection data DQA.

The DSP 100 performs various digital signal processes on the detection data DQA of the physical quantity from the detection circuit 60. The CPU 130 performs a temperature correction operation based on the detection data DQA and the temperature detection data. The DSP 100 performs a temperature compensation process on the detection data DOA based on the temperature correction value obtained by the temperature correction operation by the CPU 130. The DSP 100 then performs a digital filtering process such as a low-pass filtering process and a notch filtering process on the detection data after the temperature compensation process. Further, the CPU 130 performs a failure diagnosis process based on failure detection data DQB and DQC from the failure detection circuit 170. Details of the failure detection circuit 170 will be described later.

The storage unit 160 includes a register unit 162 and a nonvolatile memory 164. The nonvolatile memory 164 stores various pieces of information necessary for the operation of the circuit device 20. For example, a program for causing the CPU 130 to operate is stored in the nonvolatile memory 164. Examples of the nonvolatile memory 164 may include an EPROM, an EEPROM, and a flash memory. Information stored in nonvolatile memory 164 is transferred to the register unit 162. Each circuit such as the DSP 100 and the CPU 130 of the circuit device 20 operates based on information from the register unit 162 and writes various pieces of status information to the register unit 162. Further, the register unit 162 can be accessed from the outside via the interface circuit 180. The register unit 162 can be achieved by, for example, a RAM or a flip-flop circuit.

The interface circuit 180 is a circuit for communicating with an external processing device and the like. For example, the interface circuit 180 performs communication based on a given communication standard with an external processing device. For example, the interface circuit 180 performs serial communication such as an inter-integrated circuit (I2C) or a serial peripheral interface (SPI).

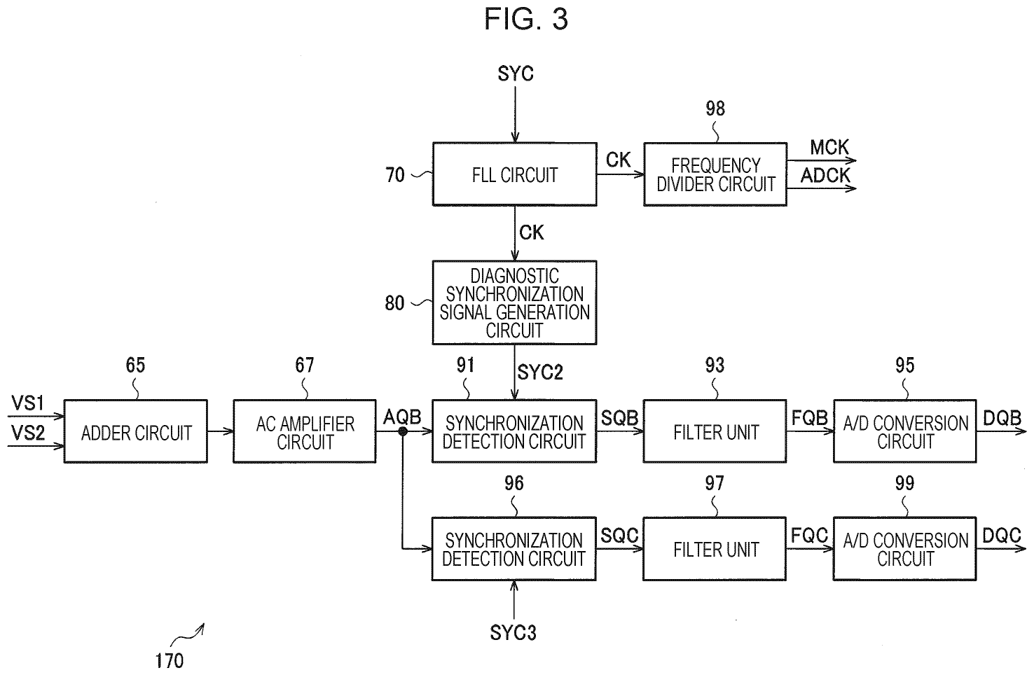

FIG. 3 shows a configuration example of the failure detection circuit 170. Note that the failure detection circuit 170 is not limited to the configuration shown in FIG. 3, and various modifications such as omitting some of these components or adding other components are possible. The failure detection circuit 170 includes an adding circuit 65, an AC amplifier circuit 67, an FLL circuit 70, a diagnostic synchronization signal generation circuit 80, synchronization detection circuits 91 and 96, filter units 93 and 97, A/D conversion circuits 95 and 99, and a frequency divider circuit 98.

The adding circuit 65 performs an additive amplification on the signals VS1 and VS2 from the Q/V conversion circuits 62 and 63 in FIG. 2. This achieves the amplification of electrostatic leakage signals and the like contained in the signals VS1 and VS2. That is, since the electrostatic leakage signals included in the signals VS1 and VS2 are signals in the same phase, the signals are amplified by performing the additive amplification. The AC amplifier circuit 67 amplifies the output signal of the adding circuit 65 to output the amplified output signal as an output signal AQB of the amplifier circuit 61.

The FLL circuit 70 is a circuit that includes an oscillation circuit and generates a clock signal CK with a target frequency using the oscillation circuit. FLL is an abbreviation for Frequency Locked Loop. For example, the FLL circuit 70 compares the frequency of the clock signal CK with a target frequency, and generates the clock signal CK having a frequency that matches the target frequency using the oscillation circuit. The FLL circuit 70 then generates the clock signal CK with the target frequency with the synchronization signal SYC based on the drive signal DS as a reference clock signal. For example, the FLL circuit 70 generates the clock signal CK whose frequency ratio with respect to the synchronization signal SYC, which is a reference clock signal, is kept constant. The frequency ratio is a multiplication rate, and constant includes substantially constant. In the FLL circuit 70, the frequency ratio of the clock signal CK to the synchronization signal SYC is locked. The synchronization signal SYC is, for example, a clock signal with the first frequency that is a frequency same as that of the drive signal DS with the first frequency. The synchronization signal SYC can also be referred to as, for example, a reference signal or a detection clock signal.

The diagnostic synchronization signal generation circuit 80 generates a failure diagnostic synchronization signal SYC2 with a second frequency based on the clock signal CK. For example, the synchronization signal SYC based on the drive signal DS with the first frequency is a signal with the first frequency, whereas the diagnostic synchronization signal SYC2 is a signal with the second frequency. As an example, the diagnostic synchronization signal SYC2 is a signal with a frequency twice the frequency of the synchronization signal SYC. In the present embodiment, for example, the FLL circuit 70 and the diagnostic synchronization signal generation circuit 80 perform synchronization processing such that the edge of the diagnostic synchronization signal SYC2 approaches the edge of the synchronization signal SYC. For example, the synchronization processing is performed such that the edge of the diagnostic synchronization signal SYC2 falls within a given range with respect to the edge of the synchronization signal SYC. This range is, for example, a range of one clock period or less of the clock signal CK. Further, the edge of the signal is a rising edge or a falling edge of the signal.

A synchronization detection circuit 91 performs synchronization detection on the output signal AQB of the AC amplifier circuit 67 based on the diagnostic synchronization signal SYC2. Since the output signal AQB is a signal obtained by performing an additive amplification on the signals VS1 and VS2, the output signal AQB includes an electrostatic leakage signal, and the electrostatic leakage signal is, for example, a signal with the second frequency. Therefore, by performing synchronization detection on the output signal AQB with the diagnostic synchronization signal SYC2 with the second frequency, it is possible to extract the electrostatic leakage signal included in the output signal AQB. A filter unit 93 then performs the filtering process such as a low-pass filtering process on an output signal SQB of the synchronization detection circuit 91. An A/D conversion circuit 95 performs an A/D conversion on an analog output signal FQB from the filter unit 93 to output the failure detection data DQB. This allows the CPU 130 to perform a failure diagnosis by detecting the presence or absence of an electrostatic leakage signal.

On the other hand, a synchronization detection circuit 96 performs synchronization detection on the output signal AQB of the AC amplifier circuit 67 based on a diagnostic synchronization signal SYC3. The diagnostic synchronization signal SYC3 is, for example, a square wave voltage signal whose phase is advanced by 90 degrees with respect to the detecting synchronization signal SYC of a physical quantity signal. Therefore, the synchronization detection circuit 96 can extract a vibration leakage signal included in the output signal AQB by performing synchronization detection on the output signal AQB based on the diagnostic synchronization signal SYC3. A filter unit 97 then performs the filtering process such as a low-pass filtering process on an output signal SQC of the synchronization detection circuit 96. An A/D conversion circuit 99 performs an A/D conversion on an analog output signal FQC from the filter unit 97 to output failure detection data DQC. This allows the CPU 130 to perform a failure diagnosis by detecting the presence or absence of a vibration leakage signal.

The frequency divider circuit 98 divides the frequency of the clock signal CK from the FLL circuit 70 to output a clock signal ADCK for A/D conversion and a master clock signal MCK of the circuit device 20 used in the DSP 100 and the like. The A/D conversion circuits 94, 95, and 99 perform an A/D conversion based on the clock signal ADCK. As an example, the clock signal CK is, for example, 8 MHZ, the master clock signal MCK is, for example, 4 MHZ, and the clock signal ADCK is, for example, about 47 to 48 KHz. For example, by shifting the clock signal ADCK for A/D conversion from the drive frequency of 50 kHz, it is possible to prevent noise caused by the A/D conversion from adversely affecting detection accuracy of the angular velocity and the like.

For example, in the present embodiment, the failure diagnosis is performed using electrostatic leakage components generated by the coupling capacitance between the drive electrode 13 and the detection electrodes 15 and 16. The coupling capacitance is an electrostatic coupling capacitance. For example, a coupling capacitance is formed between the drive electrode 13 to which the drive signal DS is supplied and the detection electrode 15 to which the detection signal S1 is output, and a coupling capacitance is also formed between the drive electrode 13 and the detection electrode 16 to which the detection signal S2 is output. In this way, the coupling capacitance is formed due to the physical structure of the electrodes of the physical quantity transducer 10, and electrostatic leakage components resulting from this coupling capacitance appear in the detection signals S1 and S2. By detecting the electrostatic leakage signal, which is this electrostatic leakage component signal, by the synchronization detection by the synchronization detection circuit 91 based on the diagnostic synchronization signal SYC2, it is possible to perform a failure diagnosis using the detection of the electrostatic leakage signal.

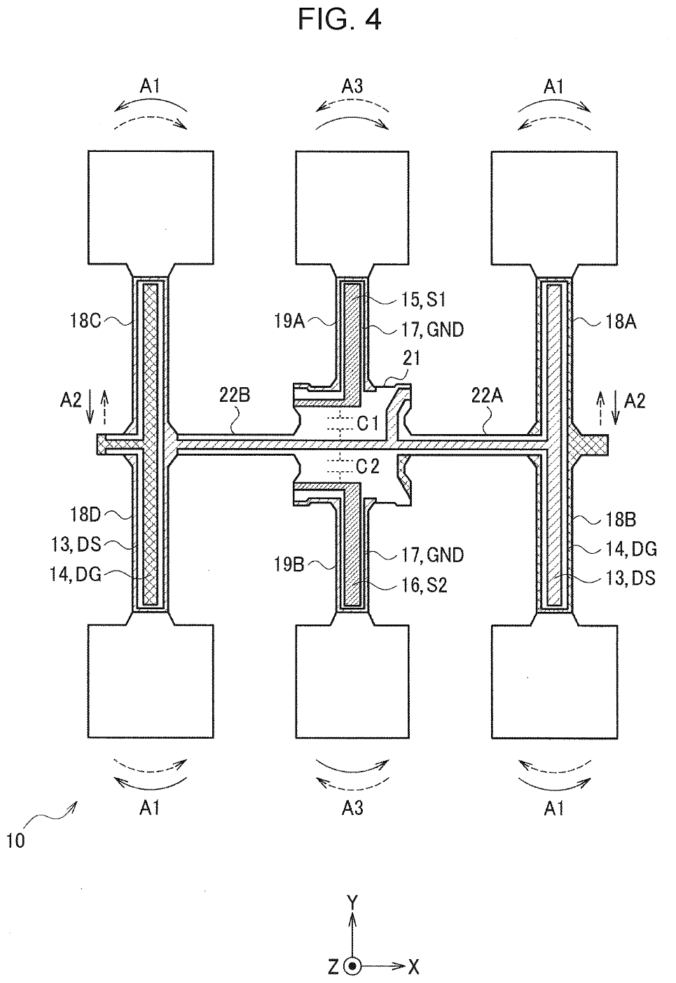

FIG. 4 shows a double T-shaped gyro sensor element as an example of the physical quantity transducer 10.

The physical quantity transducer 10 in FIG. 4 includes drive arms 18A, 18B, 18C, 18D, detection arms 19A, 19B, a base 21, and coupling arms 22A, 22B. The detection arms 19A and 19B extend from the rectangular base 21 in the +Y axis direction and in the −Y axis direction. Further, coupling arms 22A and 22B extend from the base 21 in the +X axis direction and the −X axis direction. The drive arms 18A and 18B extend from the distal end of the coupling arm 22A in the +Y axis direction and the −Y axis direction. Furthermore, the drive arms 18C and 18D extend from the distal end of the coupling arm 22B in the +Y axis direction and the −Y axis direction. Hammer heads provided at the distal ends of the drive arms 18A, 18B, 18C, 18D and the detection arms 19A, 19B are used, for example, as weights for frequency adjustment. When the Z axis is the thickness direction of the physical quantity transducer 10, the physical quantity transducer 10, which is a gyro sensor element, detects the angular velocity around the Z axis. The X axis and the Y axis are coordinate axes orthogonal to the Z axis, and the X axis and Y axis are orthogonal to each other. The vibrating piece of the physical quantity transducer 10 can be formed of a piezoelectric material such as quartz, lithium tantalate, or lithium niobate. Among these, it is preferable to use crystal as the constituent material of the vibrating piece. The X axis, the Y axis, and the Z axis are also referred to as the electrical axis, the mechanical axis, and the optical axis of the quartz substrate, respectively. The quartz substrate is composed of a plate-shaped Z-cut crystal plate or the like having a thickness in the Z axis direction.

The drive electrodes 13 are formed at the upper and lower faces of the drive arms 18A, 18B, and the drive electrodes 14 are formed at the right and left sides of the drive arms 18A, 18B. The drive electrodes 14 are formed at the upper and lower faces of the drive arms 18C and 18D, and the drive electrodes 13 are formed at the right and left sides of the drive arms 18C and 18D. The drive signal DS from the drive circuit 30 is supplied to the drive electrode 13, and the feedback signal DG from the drive electrode 14 is input to the drive circuit 30.

The detection electrodes 15 are formed at the upper and lower faces of the detection arm 19A, and the ground electrodes 17 are formed at the right and left sides of the detection arm 19A. The detection electrodes 16 are formed at the upper and lower faces of the detection arm 19B, and the ground electrodes 17 are formed at the right and left sides of the detection arm 19B. The detection signals S1 and S2 from the detection electrodes 15 and 16 are input to the detection circuit 60.

Note that grooves (not shown) are provided on the upper and lower faces of the drive arms 18A, 18B, 18C, 18D and the detection arms 19A, 19B to improve the electric field effect between the electrodes. By providing the groove, it is possible to generate a relatively large amount of charge with a relatively small amount of distortion. Further, the upper face is the +Z axis side face, and the lower face is the −Z axis side face. The right side face is the +X axis side side face, and the left side face is the −X axis side side face.

Next, the operation of the physical quantity transducer 10 shown in FIG. 4 will be described. When the drive signal DS is applied to the drive electrode 13 by the drive circuit 30, the drive arms 18A, 18B, 18C, and 18D perform the flexural vibration as shown by an arrow A1 in FIG. 4 due to the inverse piezoelectric effect. The flexural vibration is also referred to as excitation vibration. For example, the vibration state shown by the solid line of the arrow A1 and the vibration state shown by the dotted line are repeated at a predetermined frequency. That is, the flexural vibration is performed in which the distal ends of the drive arms 18A and 18C repeatedly approach and separate from each other, and the distal ends of the drive arms 18B and 18D also repeatedly approach and separate from each other. At this time, the drive arms 18A and 18B and the drive arms 18C and 18D are vibrating line-symmetrically with respect to the X axis passing through the center of gravity of the base 21, so that the base 21, the coupling arms 22A and 22B, and the detection arm 19A and 19B hardly vibrate.

In this state, when an angular velocity with the z axis as the rotation axis acts on the physical quantity transducer 10 and the physical quantity transducer 10 rotates around the Z axis, the drive arms 18A, 18B, 18C, and 18D vibrates as shown by an arrow A2 due to the Coriolis force. That is, the Coriolis force in the direction of the arrow A2 that is orthogonal to the direction of the arrow A1 and the Z axis direction acts on the drive arms 18A, 18B, 18C, and 18D, thereby generating a vibration component in the direction of the arrow A2. This vibration in the direction of the arrow A2 is transmitted to the base 21 via the coupling arms 22A and 22B, whereby the detection arms 19A and 19B perform the flexural vibration in the direction of an arrow A3. Charge signals generated by the piezoelectric effect caused by the flexural vibrations of the detection arms 19A and 19B are input to the detection circuit 60 as detection signals S1 and S2, and the angular velocity around the Z axis is detected.

For example, the Coriolis force is expressed as Fc=2m·v·ω, where ω is an angular velocity of the physical quantity transducer 10 around the Z axis, m is a mass, and v is a vibration velocity. Therefore, the detection circuit 60 detects the desired signal that is a physical quantity signal corresponding to the Coriolis force to be able to calculate the angular velocity ω around the Z axis.

In FIG. 4, a coupling capacitance C1 exists between the drive electrode 13 and the detection electrode 15, and a coupling capacitance C2 exists between the drive electrode 13 and the detection electrode 16. Therefore, when the drive electrode 13 is driven by the drive signal DS, the AC frequency component included in the drive signal DS propagates to the detection electrode 16, and an AC charge signal based on the frequency component appears in the detection signals S1 and S2. Therefore, when the drive signal DS has the second frequency component, an AC charge signal based on the second frequency component appears in the detection signals S1 and S2. Then, the adding circuit 65 performs an additive amplification on the second frequency component signals appearing in the detection signals S1 and S2, and the synchronization detection circuit 91 detects the signals based on the diagnostic synchronization signal SYC2 with the second frequency. Then, the CPU 130 determines whether a failure has occurred based on the detection result.

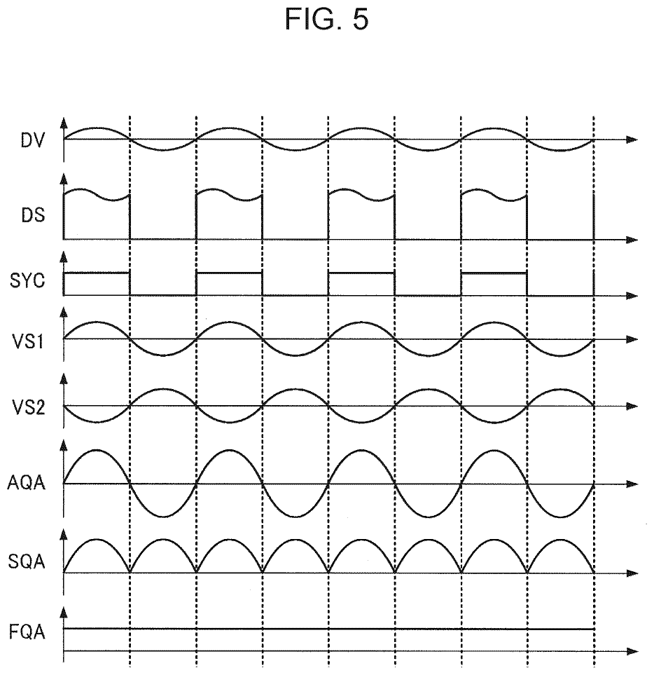

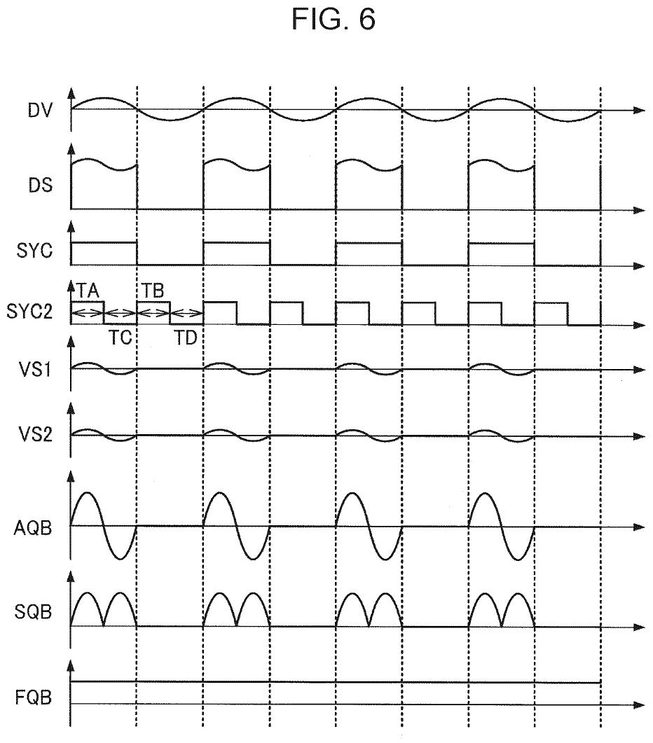

Next, the operation of the present embodiment will be described using the signal waveform diagrams of FIGS. 5 and 6. FIG. 5 is a signal waveform diagram for describing detection of the physical quantity component included in detection signals S1 and S2 of the physical quantity transducer 10.

The signal DV is an output signal of the amplifier circuit 32 of the drive circuit 30, and is an AC signal with a first frequency f1. The first frequency f1 is, for example, a drive frequency of the drive circuit 30, and is, for example, 50 kHz. The drive signal DS is a signal generated by the drive signal output circuit 50 based on the signal DV from the amplifier circuit 32. The drive signal DS is a signal in phase with the signal DV, and is a square wave voltage signal in which a high level voltage is set based on the control voltage VC from the gain control circuit 40. The drive signal DS has a component of the first frequency f1 that is a drive frequency, and a component of a second frequency f2=2×f1. The first frequency signal can also be referred to as a ω signal, and the second frequency signal can also be referred to as a 2Ω signal. For example, in the drive signal DS, a component of the second frequency f2 is superimposed on the high-level voltage. This second frequency f2 component is a component generated by the full-wave rectifier circuit 42 of the gain control circuit 40. For example, the signal obtained by full-wave rectifying the signal DV by the full-wave rectifier circuit 42 has a component of the second frequency f2, which is twice the first frequency f1, in addition to a component of the first frequency f1. This second frequency f2 component is superimposed on the control voltage VC from the integration circuit 44 that integrates the full-wave rectified signal from the full-wave rectifier circuit 42, so that the second frequency f2 component appears in high-level voltage of the drive signal DS.

The synchronization signal SYC is generated, for example, by the synchronization signal output circuit 52 shaping the sinusoidal wave (alternating current) signal DV into a square wave signal. The synchronization signal SYC is a signal in phase with the drive signal DS, and is a square wave voltage signal with the first frequency f1.

Signals VS1 and VS2 in FIG. 5 indicate the physical quantity component signals included in the output signals of the Q/V conversion circuits 62 and 63. Note that in the present embodiment, a physical quantity component signal is also referred to as a physical quantity signal as appropriate. The signals VS1 and VS2 constitute differential signals having opposite phases to each other. The amplifier circuit 61 outputs the output signal AQA generated by differentially amplifying the signals VS1 and VS2 by the differential amplifier circuit 64. The synchronization detection circuit 90 synchronously detects the output signal AQA of the amplifier circuit 61 based on the synchronization signal SYC to output the output signal SQA. The output signal SQA is a full-wave rectified signal. The filter unit 92 then outputs a DC voltage signal obtained by smoothing the output signal SQA, which is a full-wave rectified signal, as the output signal FQA. This DC voltage output signal FQA is A/D converted by the A/D conversion circuit 94 and input to the DSP 100 and the like as the digital detection data DQA. The DSP 100 detects angular velocity, which is a physical quantity, based on this detection data DOA.

FIG. 6 is a signal waveform diagram for describing detection of the electrostatic leakage component included in the detection signals S1 and S2 of the physical quantity transducer 10.

Since the signal DV, the drive signal DS, and the synchronization signal SYC are the same as those in FIG. 5, detailed description will be omitted. As shown in FIG. 6, in the present embodiment, the FLL circuit 70 and the diagnostic synchronization signal generation circuit 80 digitally generate the diagnostic synchronization signal SYC2 with the second frequency f2. That is, the FLL circuit 70 generates the clock signal CK with the target frequency using the synchronization signal SYC based on the drive signal DS as a reference clock signal. The clock signal CK is, for example, a high-speed clock signal of 8 MHZ. Then, the diagnostic synchronization signal generation circuit 80 generates the diagnostic synchronization signal SYC2 with the second frequency f2 based on this high-speed clock signal CK. The diagnostic synchronization signal SYC2 has the second frequency f2 that is twice that of the synchronization signal SYC that is a signal with the first frequency f1. For example, the diagnostic synchronization signal SYC2 is a signal whose rising edge is within, for example, one clock period of the clock signal CK with respect to the rising edge of the synchronization signal SYC.

Signals VS1 and VS2 in FIG. 6 indicate electrostatic leakage component signals included in the output signals of the Q/V conversion circuits 62 and 63. The electrostatic leakage component signals in the signals VS1 and VS2 are signals in which the second frequency component of the drive signal DS is propagated through the coupling capacitances C1 and C2 described in FIG. 4, and are in phase with each other. Then, the amplifier circuit 61 outputs the output signal AQB generated by the adding circuit 65 performing an additive amplification on the signals VS1 and VS2. The synchronization detection circuit 91 synchronously detects the output signal AQB of the amplifier circuit 61 based on the diagnostic synchronization signal SYC2 to output the output signal SQB of the full-wave rectified signal. The electrostatic leakage component signals in the signals VS1 and VS2 are signals of the second frequency component of the drive signal DS propagated by the coupling capacitances C1 and C2, and thus are signals with the second frequency f2. Therefore, by performing synchronization detection using the diagnostic synchronization signal SYC2 with the second frequency f2, the electrostatic leakage component can be detected. The filter unit 93 in FIG. 3 then outputs a DC voltage signal obtained by smoothing the output signal SQB, which is a full-wave rectified signal, as the output signal FQB. This DC voltage output signal FOB is A/D converted by the A/D conversion circuit 95 and input to the CPU 130 as the digital failure detection data DQB. The CPU 130 performs a failure diagnosis based on the failure detection data DQB. For example, the CPU 130 determines that no failure has occurred when an electrostatic leakage component signal is detected by the synchronization detection circuit 91. On the other hand, when the electrostatic leakage component signal is not detected by the synchronization detection circuit 91, the CPU 130 determines that a failure such as a disconnection has occurred.

The CPU 130 also performs failure diagnosis using mechanical leakage based on the failure detection data DOC due to mechanical leakage from the failure detection circuit 170.

In FIG. 5, the signals VS1 and VS2 are differentially amplified by the differential amplifier circuit 64, so that the in-phase electrostatic leakage component signals appearing in the signals VS1 and VS2 in FIG. 6 hardly appear in the output signal AQA and is not detected by the synchronization detection circuit 90. On the other hand, in FIG. 6, since the adding circuit 65 performs additive amplification on the signals VS1 and VS2, the physical quantity component signals of the differential signals appearing in the signals VS1 and VS2 in FIG. 5 hardly appears in the output signal AQB, and are not detected by the synchronization detection circuit 91.

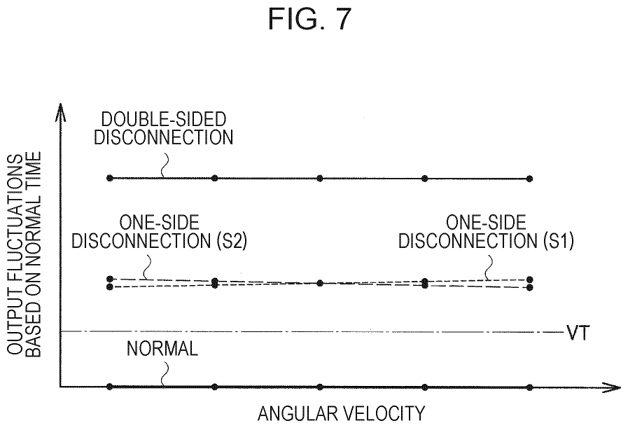

FIG. 7 is an explanatory diagram of the angular velocity dependence of the failure diagnosis result in the present embodiment. The horizontal axis represents an angular velocity, which is a physical quantity, and the vertical axis represents an output fluctuation based on the normal time. The output fluctuation based on the normal time represents the amount of change that has been corrected to be 0 during the normal time when no disconnection occurs. VT is a threshold value used for failure diagnosis. Since the output fluctuation is below the threshold value VT during normal conditions, the CPU 130 determines that no abnormality has occurred. On the other hand, in a double-sided disconnection in which disconnections occur on both the detection signal S1 side and the detection signal S2 side, the output fluctuation exceeds the threshold value VT, so that the CPU 130 determines that an abnormality has occurred. Furthermore, even in the case of a one-side disconnection in which a disconnection occurs only on the detection signal S1 side or only on the detection signal S2 side, the output fluctuation exceeds the threshold value VT, so that the CPU 130 determines that an abnormality has occurred.

For example, in a case where a one-side disconnection has occurred, even when the adding circuit 65 in FIG. 2 performs an additive amplification on the signals VS1 and VS2, the physical quantity component signals remain in the output signal AQB of the amplifier circuit 61 without canceling each other. That is, the physical quantity component signal corresponding to the signal DV in FIG. 6 remains in the output signal AQB. In this case, when the duty ratio of the diagnostic synchronization signal SYC2 is 50%, the physical quantity component signal of the diagnostic synchronization signal SYC2 after the synchronization detection in a period TA and the physical quantity component signal after the synchronization detection in a period TB in FIG. 6 cancel out each other and do not appear in the output signal FOB of the filter unit 93. This is because when the duty ratio of the diagnostic synchronization signal SYC2 is 50%, the period TA and the period TB have the same length. Similarly, the physical quantity component signal after synchronization detection in a period TC and the physical quantity component signal after synchronization detection in a period TD cancel out each other, and do not appear in the output signal FQB of the filter unit 93. Therefore, no physical quantity component signal appears in the output signal FQB of the filter unit 93, and it is possible to detect only the electrostatic leakage component signal.

On the other hand, when the duty ratio of the diagnostic synchronization signal SYC2 cannot be maintained, the lengths of the periods TA and TB are different, or the lengths of the periods TC and TD are different. Therefore, the physical quantity component signal after synchronization detection in the period TA and the physical quantity component signal after synchronization detection in the period TB in FIG. 6 remain without canceling out each other. Further, the physical quantity component signal after synchronization detection in the period TC and the physical quantity component signal after synchronization detection in the period TD also remain without canceling out each other. As a result, the physical quantity component signal remains in the output signal FQB of the filter unit 93, and, for example, when a one-side disconnection has occurred, angular velocity dependence occurs in the failure diagnosis result. Therefore, when it is determined whether an abnormality has occurred in comparison with the threshold value VT, a problem arises that an incorrect abnormality diagnosis is performed.

In this regard, in the present embodiment, the diagnostic synchronization signal SYC2 is generated by digital processing by the FLL circuit 70 and the diagnostic synchronization signal generation circuit 80. Therefore, generation of the diagnostic synchronization signal SYC2 with mixed duty ratios can be prevented, and the duty ratio of the diagnostic synchronization signal SYC2 can be maintained. For example, the period TA and the period TB can have the same period, and the period TC and the period TD can have the same period in FIG. 6, and the diagnostic synchronization signal SYC2 with a duty ratio of 50%, for example, can be digitally generated. This prevents the output fluctuation from depending on the angular velocity in even in the case of a one-side disconnection. Therefore, when the output fluctuation is below the threshold value VT, it can be determined that the state is normal without any abnormality, and when the output fluctuation is above the threshold value VT, it can be appropriately determined that an abnormality such as a one-side disconnection or a double-sided disconnection has occurred.

As described above, the circuit device 20 of the present embodiment includes the drive circuit 30 that drives the physical quantity transducer 10, the detection circuit 60 that detects the physical quantity based on the detection signals S1 and S2 from the physical quantity transducer 10, and outputs the detection data DQA of the physical quantity, and the DSP 100 that performs a digital signal process on detection data DOA. The circuit device 20 also includes the storage unit 160 that stores a program in which a plurality of instructions is written, and the CPU 130 that operates based on the stored program to perform at least one of a temperature correction operation of the detection data DQA and a failure diagnosis. For example, the CPU 130 performs the temperature correction operation to obtain a temperature correction value for the temperature compensation process based on the detection data DQA of the detection circuit 60. Alternatively, the CPU 130 performs a failure diagnosis of the circuit device 20 and the physical quantity detection device 5 based on the failure detection data DQB and DQB, and the like from the failure detection circuit 170.

In this way, the operation of the detection data DQA of the physical quantity such as an angular velocity can be performed by the high-speed DSP 100, and the operation such as a temperature correction and a failure diagnosis can be performed by the CPU 130 with a high degree of freedom. For example, the DSP 100 is a circuit specialized for calculating the detection data DQA, so that it is possible to perform a digital signal process such as a digital filtering process on the detection data DQA at high speed. Further, since the CPU 130 operates based on the program stored in the storage unit 160, the CPU 130 can perform the arithmetic process with a high degree of freedom. For example, by performing physical quantity detection processing using the DSP 100 capable of high-speed processing, the detection value of the physical quantity can be output without delay. Furthermore, the CPU 130 that operates based on a program can perform a failure diagnosis, a temperature operation, and the like with a high degree of freedom. For example, by preparing two computing units of the circuit device 20 and performing a cooperative operation, the high-speed operation and the highly reliable operation can be achieved. One of the two computing units is the CPU 130, and can be operated programmably by a program stored in the storage unit 160. For example, the CPU 130 may perform a calculation of a temperature correction value such as a temperature characteristic coefficient to be passed to the DSP 100, a failure diagnosis calculation, a comparison of detection results between the DSP 100 and the CPU 130, a core calculation of a neural network, or an angle calculation based on the angular velocity. The other of the two computing units is the DSP 100 that performs a physical quantity calculation such as an angular velocity calculation, and the DSP 100 performs a temperature compensation process using the temperature correction value received from the CPU 130, and various digital filtering processes such as those using a low-pass filter, a notch filter, and a user-defined filter. For example, the CPU 130 and the DSP 100 perform cooperative operations while exchanging data with each other. For example, the CPU 130 performs more complex calculation and after the results are determined, the results are reflected in the DSP 100, so that even when complex and highly accurate calculation is performed, it is possible not to affect the output intervals of the physical quantity such as the angular velocity. For example, it is possible to perform a failure diagnosis without affecting calculation of the physical quantity such as the angular velocity. Furthermore, the operation speed of the failure diagnosis itself is increased, and the probability of erroneously determining a failure can be reduced.

### 3. DSP and CPU

Next, specific examples of the DSP 100 and CPU 130 will be described. In the present embodiment, the CPU 130 for controlling the physical quantity transducer 10 is provided. A program for causing the CPU 130 to operate is transferred from the nonvolatile memory 164 to a volatile memory such as an SRAM when the power is turned on, for example. Volatile memory is provided in the storage unit 160. The CPU 130 then reads the program from the volatile memory and operates. A volatile memory is used as the data memory, and initial values can be transferred to the data memory in the CPU boot operation. It is also possible to transfer the initial value to the data memory when the power is turned on by setting. The CPU 130 operates according to a program with a 16-bit instruction length set and a 5-bit operation code, for example. For example, the volatile memory can store up to 512 instructions. The CPU 130 can perform, for example, 16-bit fixed-point calculation and 32-bit floating-point calculation, as well as fixed-point and floating-point conversion calculation. The operation cycle of the CPU 130 is fixed at, for example, three cycles, but a NOP instruction is input after a branch instruction. The CPU 130 has a built-in stack frame and a built-in stack pointer, and supports calling subroutines (functions). Further, the CPU 130 supports neural network calculation and has a built-in watchdog timer for monitoring the operation of the CPU 130. The CPU 130 also includes a crystal clock counter, a threshold value determination circuit, a PWM waveform output circuit, a GPIO control circuit, a comparison circuit for failure diagnosis, and the like as peripheral circuits. For example, the operation frequency of the DSP 100 is about 12 kHz, and the CPU 130 operates at an operation frequency obtained by dividing the operation frequency of the DSP 100 by, for example, 1, 4, 6, or 12.

The DSP 100 is equipped with, for example, a second to fourth order IIR low-pass filter, a digital arithmetic unit, a clip process, a fourth order notch filter, and a user-defined filter. It is possible to set the on/off, the order, and the cutoff frequency for the low-pass filter. Since the cutoff frequency of the low-pass filter changes depending on the drive frequency of the physical quantity transducer 10 such as a gyro sensor, the low-pass filter has a function of automatically adjusting the filter coefficient. On or off can be set for the notch filter. The output scale and the output polarity can be changed using the register. In order to avoid conflicting with the non-determination even when the gain is lowered by the user-defined filter, a clip processing unit that clips to ±500 dps, for example, is installed, and a watchdog timer is also installed before the user-defined filter.

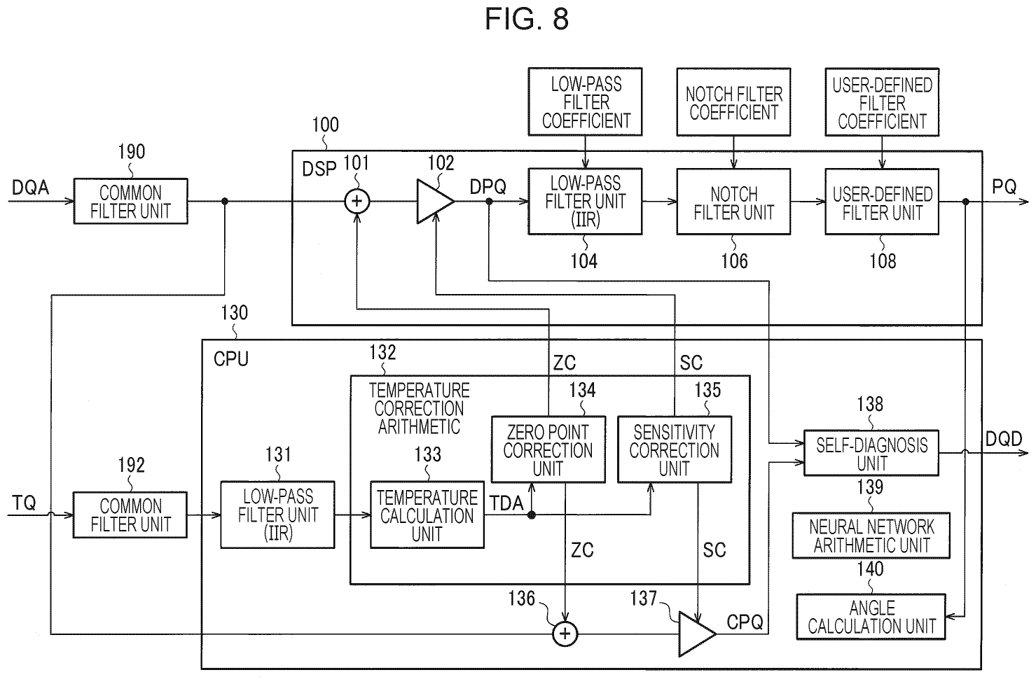

FIG. 8 is a block diagram showing a detailed configuration example of the DSP 100 and the CPU 130. The detection data DQA of the physical quantity such as the angular velocity is input to the DSP 100 and the CPU 130 via a common filter unit 190. A temperature detection signal TQ is input to the CPU 130 via a common filter unit 192. The common filter units 190 and 192 perform the filtering process such as moving average, for example. The temperature detection signal TQ is input from a temperature sensor (not shown).

The DSP 100 includes an addition unit 101, a gain processing unit 102, a low-pass filter unit 104, a notch filter unit 106, and a user-defined filter unit 108. The CPU 130 includes a low-pass filter unit 131, a temperature correction arithmetic unit 132, an addition unit 136, a gain processing unit 137, a self-diagnosis unit 138, a neural network arithmetic unit 139, and an angle calculation unit 140. The temperature correction arithmetic unit 132 includes a temperature calculation unit 133, a zero point correction unit 134, and a sensitivity correction unit 135. The programs stored in the storage unit 160 are programs for operating the CPU 130 as respective parts of the CPU 130. Note that the DSP 100 and CPU 130 are not limited to the configuration shown in FIG. 8, and various modifications such as omitting some of these components or adding other components are possible.

The low-pass filter unit 131 of the CPU 130 performs a low-pass filtering process using, for example, an infinite impulse response (IIR) on the temperature detection signal TQ input via the common filter unit 192. The temperature calculation unit 133 of the temperature correction arithmetic unit 132 performs a process of calculating temperature data TDA based on the temperature detection signal TQ after the low-pass filtering process.

The zero point correction unit 134 of the temperature correction arithmetic unit 132 calculates a temperature correction value ZC for zero point correction based on the temperature data TDA. The zero point correction is also referred to as offset correction, and is correction for making the detection value of the angular velocity zero when the angular velocity is zero. For example, the zero point correction unit 134 approximates the output fluctuation characteristic of the angular velocity with respect to temperature with, for example, a quartic function, and calculates the temperature correction value ZC by reversing the sign of the approximate value. Then, the addition unit 101 of the DSP 101 performs the addition process of the temperature correction value ZC, which is an offset correction value, thereby achieving zero point correction of the detection data DOA.

The sensitivity correction unit 135 of the temperature correction arithmetic unit 132 calculates a temperature correction value SC for sensitivity correction based on the temperature data TDA. Sensitivity correction is also referred to as gain correction. For example, the sensitivity correction unit 135 approximates the output sensitivity fluctuation characteristic of the angular velocity with respect to temperature with, for example, a quartic function, and calculates the temperature correction value SC by inverting the sign of the approximate value. Then, the gain processing unit 102 of the DSP 101 performs a gain adjustment process using the temperature correction value SC, which is a gain correction value, thereby achieving sensitivity correction of the detection data DOA.

By performing such zero point correction and sensitivity correction, the temperature compensation process on the detection data DOA of the detection circuit 60 is achieved. For example, the temperature compensation process that suppresses fluctuations in a detection value PQ of the angular velocity with respect to temperature fluctuations is achieved.

The low-pass filter unit 104 of the DSP 100 then performs a digital low-pass filtering process on data DPQ after such zero point correction and sensitivity correction are performed. The filter coefficient for this low-pass filtering process is stored, for example, in the register unit 162 of the storage unit 160.

Furthermore, the notch filter unit 106 performs a notch filtering process on the data after the low-pass filtering process. The notch filtering process is, for example, a filtering process for attenuating (removing) the detuned frequency component. The filter coefficient for this notch filtering process is stored, for example, in the register unit 162 of the storage unit 160.

Further, the user-defined filter unit 108 performs a user-defined filtering process on the data after the low-pass filtering process or the notch filtering process. Then, for example, the user-defined filter unit 108 outputs the detection value PQ of the angular velocity, which is a physical quantity. The user-defined filtering process is a filtering process in which the characteristic such as the filter coefficient is configured to be set by the user. For example, the user-defined filtering process is a filtering process whose characteristic is configured to be set via the interface circuit 180 of FIG. 2. Setting of the characteristic of the filtering process is, for example, setting of a filter order and a frequency characteristic. Information regarding the setting of the characteristic of this user-defined filtering process is written and stored in the register unit 162 of the storage unit 160 via the interface circuit 180, for example.

Further, the addition unit 136 of the CPU 130 performs zero point correction of the detection data DQA by performing the addition process of the temperature correction value ZC that is an offset correction value. Further, the gain processing unit 137 of the CPU 130 performs sensitivity correction of the detection data DQA by performing a gain process using the temperature correction value SC that is a gain correction value.

The self-diagnosis unit 138 then performs a comparison process between the data DPQ generated by the zero point correction and the sensitivity correction by the DSP 100 and the data CPQ generated by the zero point correction and the sensitivity correction by the CPU 130. Then, based on the result of a comparison process between the data DPQ generated by the DSP and the data CPQ generated by the CPU, a failure diagnosis of the DSP 100 and the CPU 130 is performed. For example, when the data DPQ generated by the DSP and the data CPQ generated by the CPU match within a given determination range (reference range), the self-diagnosis unit 138 determines that no failure has occurred, and when the data DPQ generated by the DSP and the data CPQ generated by the CPU do not match, the self-diagnosis unit 138 determines that a failure has occurred. The self-diagnosis unit 138 then outputs failure detection data DOD indicating the diagnosis result.

The neural network arithmetic unit 139 performs various arithmetic processes using a neural network. For example, the storage unit 160 in FIG. 2 stores a trained model using a neural network. Then, the neural network arithmetic unit 139 inputs the data to be processed into the trained model to output the output data of the trained model as arithmetic result data of the neural network. For example, a trained model is prepared that has learned the temperature compensation process that cannot be approximated with a quartic function, the temperature compensation process for DIP in temperature characteristics, and the like. For example, the trained model that has been trained to output temperature correction values obtained by these temperature compensation processes in response to input of the temperature data TDA is prepared and stored in the storage unit 160. Then, the neural network arithmetic unit 139 performs a neural network operation using the trained model to perform these temperature compensation processes.

The angle calculation unit 140 performs a calculation process of obtaining an angle based on the detection value of the angular velocity output by the DSP 100. For example, the angle calculation unit 140 calculates the angle by performing an integration process on the detection value of the angular velocity.

As described above, in the present embodiment, the CPU 130 calculates the temperature correction values ZC and SC by performing the temperature correction operation based on the temperature data TDA. For example, the zero point correction unit 134 of the CPU 130 calculates the temperature correction value ZC for zero point correction by performing the arithmetic process for zero point correction based on the temperature data TDA. Furthermore, the sensitivity correction unit 135 of the CPU 130 calculates the temperature correction value SC for sensitivity correction by performing the arithmetic process for sensitivity correction based on the temperature data TDA. Then, the DSP 130 performs the temperature compensation process on the detection data DOA based on the temperature correction values ZC and SC. For example, the addition unit 101 of the DSP 100 performs the addition process based on the temperature correction value ZC from the CPU 130, thereby achieving zero point correction in the temperature compensation process. Furthermore, the gain processing unit 102 of the DSP 100 performs the gain process based on the temperature correction value SC from the CPU 130, thereby achieving sensitivity correction in the temperature compensation process. In this way, the CPU 130 executes the temperature correction operation, which is a complicated arithmetic process, to be able to obtain an appropriate temperature correction value. Further, since the CPU 130 can operate programmably based on the program stored in the storage unit 160, there is an advantage that, for example, various variations of the temperature correction operations can be achieved. On the other hand, the DSP 100 that can operate faster than the CPU 130 executes the temperature compensation process based on the temperature correction value. This makes it possible to perform a high-speed temperature compensation process on the detection data DQA of the physical quantity.

Further, in the present embodiment, the CPU 130 performs a comparison process between the DSP-generated data DPQ generated by the DSP 100 performing the temperature compensation process based on the temperature correction values ZC and SC, and the CPU-generated data CPQ generated by the CPU 130 performing the temperature compensation process based on the temperature correction values ZC and SC. The CPU 130 then diagnoses the failure of the DSP 100 and the CPU 130 based on the result of the comparison process. In FIG. 8, the self-diagnosis unit 138 performs comparison process and the failure diagnosis process. For example, when the CPU 130 determines that the data DPQ generated by the DSP and the data CPQ generated by the CPU match, the CPU 130 determines that no failure has occurred in the DSP 100 or the CPU 130. On the other hand, when the CPU 130 determines that the data DPQ generated by the DSP and the data CPQ generated by the CPU do not match, the CPU 130 determines that a failure has occurred in the DSP 100 or the CPU 130. For example, when the data DPQ generated by the DSP and the data CPQ generated by the CPU do not match, it is assumed that a problem occurs in the temperature correction operation by the temperature correction arithmetic unit 132, or a problem occurs in the temperature compensation process by the zero point correction or sensitivity correction by the DSP 100. Therefore, in this case, it is determined that the failure has occurred in the DSP 100 or the CPU 130. In this way, by comparing the result of the temperature compensation process by the DSP 100 based on the temperature correction value calculated by the CPU 130 with the result of the temperature compensation process by the CPU 130 based on the temperature correction value calculated by the CPU 130, the DSP 100 and the CPU 130 can perform the self-failure diagnosis. By performing such a self-failure diagnosis, it is possible to improve the reliability and the like of the circuit device 20 and the physical quantity detection device 5.

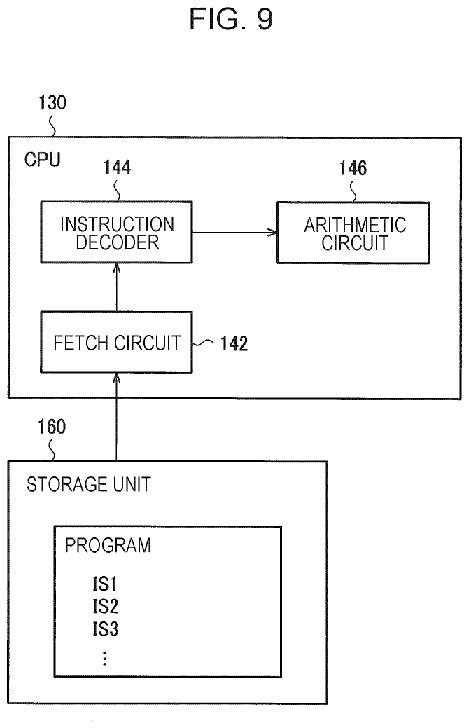

FIG. 9 shows an example of the hardware configuration of the CPU 130. As shown in FIG. 9, the CPU 130 includes a fetch circuit 142, an instruction decoder 144, and an arithmetic circuit 146. These circuits are provided in the core circuit of the CPU 130. The fetch circuit 142 fetches a program instruction. For example, a plurality of instructions IS1, IS2, and IS3 is written in the program stored in the storage unit 160. The fetch circuit 142 fetches each of these instructions. The instruction decoder 144 then decodes the instruction fetched by the fetch circuit 142. For example, the instruction decoder 144 decodes the instruction by decoding the code of the instruction. The arithmetic circuit 146 performs the arithmetic process based on the decoding result by the instruction decoder 144. For example, the arithmetic circuit 146 performs an arithmetic operation such as an addition or a subtraction, a shift operation such as a logical shift or an arithmetic shift, and a logical operation such as AND, OR, or XOR. In this way, the instruction of the program stored in the storage unit 160 can be fetched by the fetch circuit 142, the fetched instruction can be interpreted by the instruction decoder 144, and the arithmetic process based on the interpretation result can be executed by the arithmetic circuit 146. This allows the CPU 130 that is capable of performing various operations based on the program to execute various processes for detecting the physical quantity and the like.

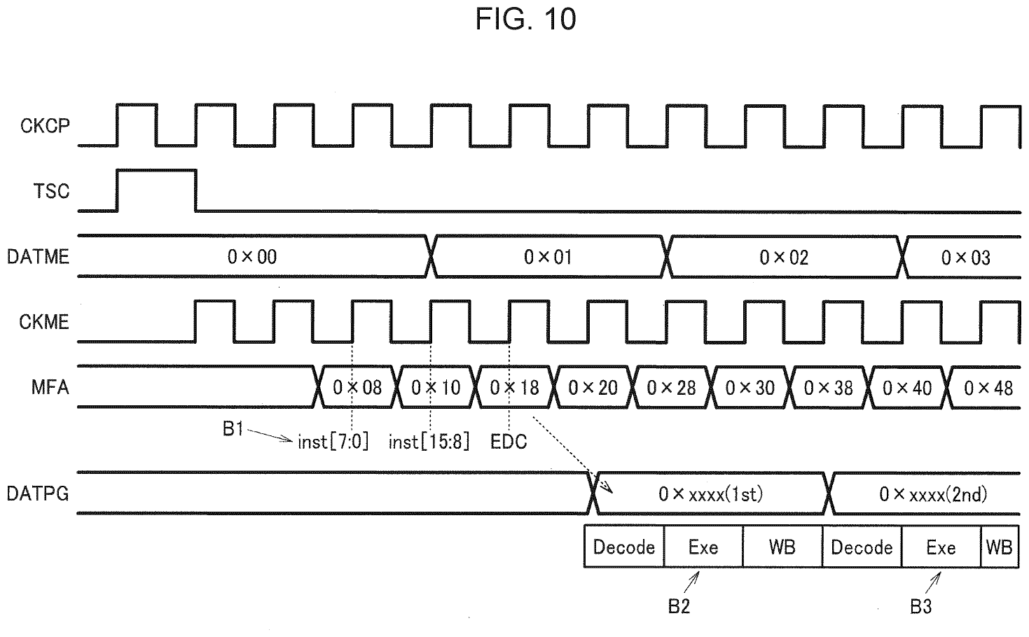

FIG. 10 is a signal waveform diagram illustrating an example of the operation of the CPU 130. CKCP in FIG. 10 is an operating clock signal of the CPU 130. The CPU 130 starts processing when a trigger start signal TSC is activated. DATME represents memory data in the storage unit 160, and CKME is a memory clock signal. Since the memory bus width of the storage unit 160 is 8 bits, as shown in B1 of FIG. 10, reading inst[15:0], which is a 16-bit instruction, requires a two-cycle period. After reading the instruction, an 8-bit EDC for bit error detection/correction is read, and when it is determined that there is no bit error, the instruction is fetched to the CPU 130. After that, as shown in B2 and B3, the CPU 130 performs three cycles of processing for each instruction: an instruction decoding process (Decode), an arithmetic logic unit (ALU) execution process (Exe), and a write back process (WB).

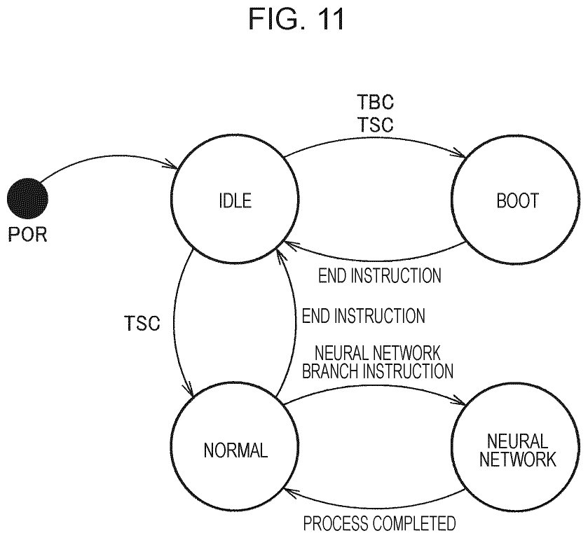

FIG. 11 is a state transition diagram describing the operation of the CPU 130. After the power-on reset (POR), the CPU 130 transitions to an idle state. Then, the CPU 130 waits until the trigger start signal TSC shown in FIG. 10 is issued. When the trigger start signal TSC and a trigger boost signal TBC are issued simultaneously, the operation mode of the CPU 130 is a boot operation mode. When only the trigger start signal TSC is issued, the operation mode of the CPU 130 is a normal operation mode. The difference between the boot operation and the normal operation is that the starting position of the program counter is different. For the boot operation, the program counter starts from ADR:1. For the normal operation, the program counter starts from zero. For either operation, after the END instruction is issued, the CPU 130 enters an idle state and waits until the trigger start signal TSC is issued again. The boot operation is assumed to be executed only once, for example, after power is turned on. Further, in the normal operation mode, when a branch instruction to the neural network is executed, the mode shifts to the neural network operation mode, and when the process is completed, the mode returns to the normal operation mode.

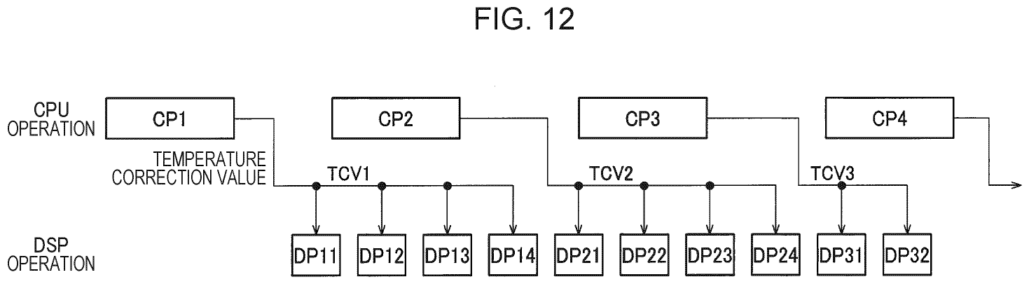

FIG. 12 is an explanatory diagram of the cooperative operation of the CPU 130 and the DSP 100. A CP1 to a CP4 in FIG. 12 represent respective processes performed by the CPU 130, and a DP11 to a DP32 represent respective processes performed by the DSP 100. For example, the DSP 100 executes the processes DP11 to DP14 using a temperature correction value TCV1 obtained by the CPU 130 in the process CP1. For example, the temperature correction value TCV1 obtained by the CPU 130 in the process CP1 is latched in the register unit 162, and the DSP 100 executes the processes DP11 to DP14 using the latched temperature correction value TCV1. Furthermore, the DSP 100 executes the processes DP21 to DP24 using a temperature correction value TCV2 obtained by the CPU 130 in the process CP2. For example, the temperature correction value TCV2 obtained by the CPU 130 in the process CP2 is latched in the register unit 162, and the DSP 100 executes the processes DP21 to DP24 using the latched temperature correction value TCV2. Similarly, the DSP 100 executes the processes DP31 to DP32 using a temperature correction value TCV3 obtained by the CPU 130 in the process CP3. As described above, in the present embodiment, the cooperative operation is possible in which the CPU 130 executes a relatively complicated process such as the temperature correction operation, and the DSP 100 that is capable of a high-speed operation performs a plurality of processes at a high speed using the temperature correction value and the like obtained by the CPU 130 through this process.

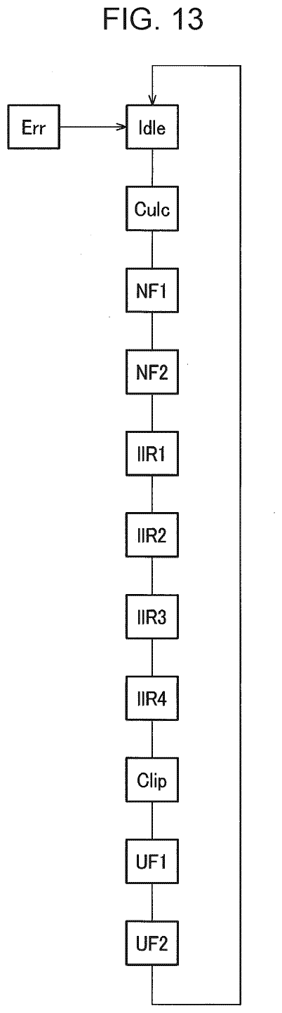

FIG. 13 is a diagram showing an example of an execution sequence of the DSP 100. “Idle” indicates idle, and “Culc” indicates a digital process such as a temperature compensation process. Further, each of NF1 and NF2 indicates the notch filtering process, each of IIR1 to IIR4 indicates the low-pass filtering process by IIR, “Clip” indicates a clip process, and each of UF1 and UF2 indicates the user-defined filtering process. The DSP 100 sequentially executes each process in the execution sequence shown in FIG. 13. In the present embodiment, the DSP 100 is configured to execute all the sequences shown in FIG. 13 in order to prevent a problem that zero point fluctuations due to fluctuations in current consumption due to a difference in the number of execution sequences of the DSP 100. For example, when jumping to a non-existent state, an error flag will be raised.

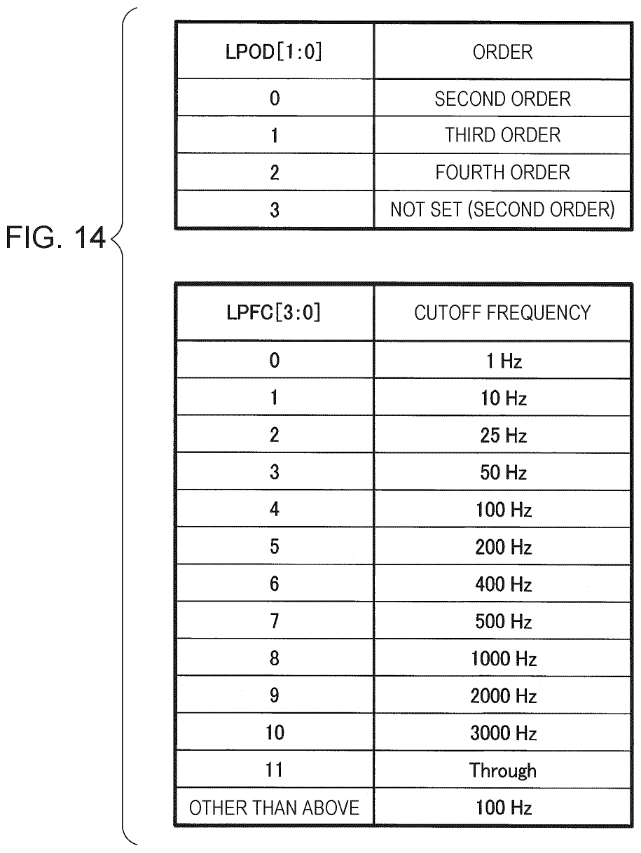

Next, details of the digital filtering process performed by the DSP 100 will be described. FIG. 14 is an explanatory diagram of the low-pass filtering process performed by the low-pass filter unit 104 of FIG. 8. In the low-pass filtering process, it is possible to set the order and the cutoff frequency as filter setting. For example, as shown in FIG. 14, the second, third, and fourth orders can be set using LPOD[1:0]. Furthermore, cutoff frequency of, for example, 1, 10, 25, 50, 100, 200, 400, 500, 1000, 2000, or 3000 Hz can be set by LPFC[3:0]. This cutoff frequency is set to a frequency corresponding to the drive frequency of the drive circuit 30, for example. Note that the default setting is normal filter setting (for example, the second order and a cutoff frequency of 100 Hz).

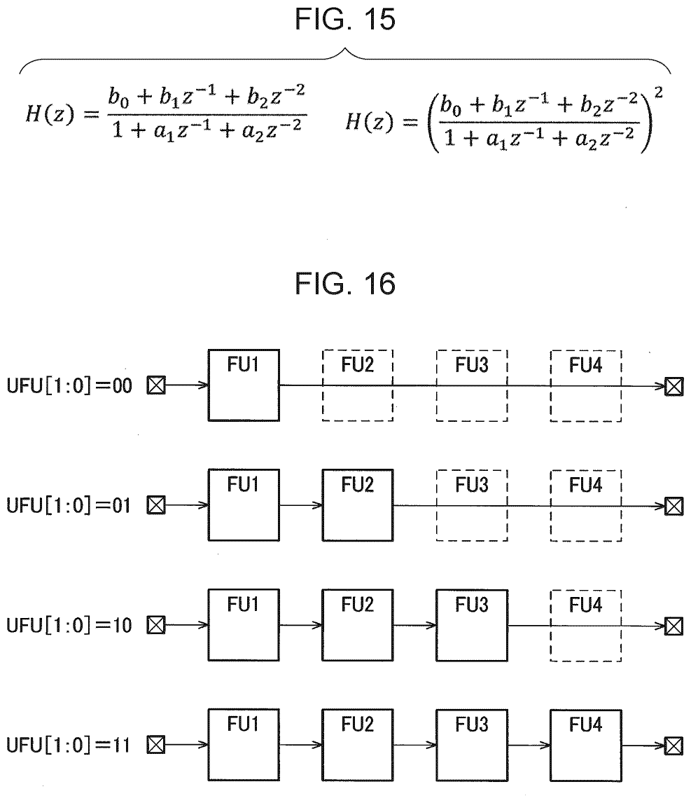

Furthermore, the notch filter unit 106 performs the notch filtering process of attenuating the component in a given frequency band. For example, the notch filter unit 106 performs the notch filtering process of attenuate the detuned frequency component. For example, in the physical quantity transducer 10 such as a gyro sensor, the generation of unnecessary signals with the detuned frequency caused by mechanical vibrations such as disturbances poses a problem. For this reason, the notch filter unit 106, which is a band elimination filter, performs the notch filtering process of attenuating the detuned frequency component. For example, when the drive side resonance frequency is fd and the detection side resonance frequency is fs, the notch filter unit 106 performs the notch filtering process of attenuating the component of the detuned frequency Δf=|fd−fs|. This makes it possible to prevent deterioration in detection accuracy and the like caused by an unnecessary signal with the detuned frequency. For example, in the notch filter unit 106, the second order or fourth order can be selected as the order. The left side of FIG. 15 shows an example of a transfer function of the notch filtering process when the order is the second order, and the right side of FIG. 15 shows an example of a transfer function of the notch filtering process when the order is the fourth order. Each coefficient of these transfer functions can be set by register setting of the register unit 162.

FIG. 16 is an explanatory diagram of the user-defined filtering process performed by the user-defined filter unit 108. In the user-defined filtering process, up to four filter units (FU) capable of processing up to the second order can be coupled in series. This makes it possible to support orders up to second order×4 units=eighth order. The number of filter units used coupled in series can be set by UFU[1:0], which is the setting value of the filter unit usage number setting register. For example, as shown in FIG. 16, when UFU[1:0]=00, only one filter unit FU1 is coupled. When UFU[1:0]=01, two filter units FU1 and FU2 are coupled in series. When UFU[1:0]=10, three filter units FU1, FU2, and FU3 are coupled in series. When UFU[1:0]=11, four filter units FU1, FU2, FU3, and FU4 are coupled in series.

As described above, in the present embodiment, the DSP 100 performs, as the digital filtering process, the low-pass filtering process in which the cutoff frequency is set according to the drive frequency of the drive circuit 30. For example, the cutoff frequency of the low-pass filtering process shown in FIG. 14 is set according to the drive frequency of the drive circuit 30. Specifically, LPFC[3:0] in FIG. 14 is set according to the drive frequency. For example, when the drive frequency is low, the cutoff frequency is set to a low cutoff frequency, and when the drive frequency is high, the cutoff frequency is set to a high cutoff frequency. For example, in FIG. 2, the optimum drive frequency for the vibration of the vibrating pieces 11 and 12 of the physical quantity transducer 10 differs depending on the characteristics, materials, types, and the like of the vibrating pieces 11 and 12. Therefore, when the optimum drive frequency is high, the cutoff frequency is set high, and when the optimum drive frequency is low, the cutoff frequency is set low. In this way, the cutoff frequency of the low-pass filtering process can be set to an appropriate cutoff frequency according to the optimal drive frequency of the physical quantity transducer 10. This makes it possible to appropriately attenuate the frequency component of an unnecessary signal that degrade detection accuracy through the low-pass filtering process to improve detection accuracy.

Further, the DSP 100 performs the notch filtering process as the digital filtering process. For example, as described with reference to FIG. 15, the DSP 100 performs the notch filtering process of attenuating the component in a given frequency band. For example, when an unnecessary signal with a detuned frequency is generated in the physical quantity transducer 10 such as a gyro sensor, the DSP 100 performs the notch filtering process of attenuating the component of the detuned frequency. In this way, the detection accuracy can be improved by attenuating the frequency component that deteriorates the detection accuracy through the notch filtering process.

Further, the DSP 100 performs, as the digital filtering process, the filtering process whose characteristic is configured to be set. Using FIG. 16 as an example, by setting the number of filter units coupled in series, it is possible to set the characteristic of the user-defined filtering process. The characteristic of this filtering process can be set via the interface circuit 180 in FIG. 2. For example, the characteristic of the filtering process is configured to be set by an external processing device writing setting information about the characteristic of the filtering process into the register unit 162 via the interface circuit 180. In this way, it is possible to cause the DSP 100 to perform the filtering process desired by the user, and cause the circuit device 20 to output the detection value of the physical quantity on which the desired filtering process was performed. Therefore, it is possible to provide the circuit device 20 and the physical quantity detection device 5 that can meet the various demands of the user.

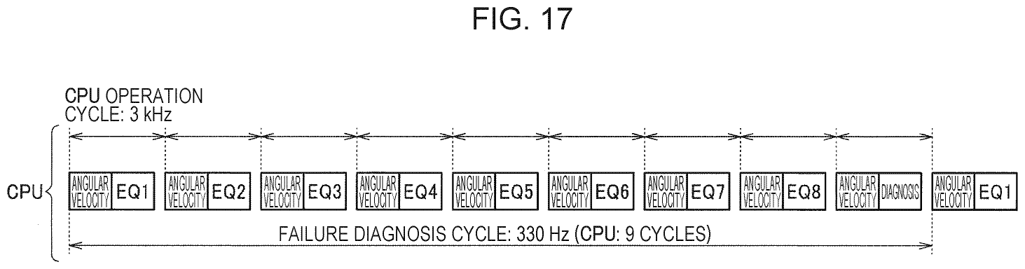

Next, the operation cycles and operation frequencies of the DSP 100 and the CPU 130 will be described. For example, FIG. 17 is a diagram illustrating the operation of the CPU 130 in a comparative example of the present embodiment. In this comparative example, the DSP 100 does not include the circuit device 20, and various processes is performed only by the CPU 130. For example, in FIG. 17, the operation cycle of the CPU 130 corresponds to an operation frequency of 3 kHz, and in each operation cycle, the angular velocity process and the failure diagnosis process are performed. EQ1 to EQ8 in FIG. 17 represent failure diagnosis processing. As an example, EQ1 is a failure diagnosis process using the electrostatic leakage component described in FIGS. 3 and 7, and EQ2 is a failure diagnosis process using the mechanical leakage component. Further, the EQ3 is a self-failure diagnosis process using the data DPQ generated by the DSP and the data CPQ generated by the CPU described in FIG. 8. Further, EQ4 to EQ8 are other failure diagnosis processes. In the last operation cycle of the CPU 130, a final failure diagnosis determination process is performed using the results of EQ1 to EQ8. As a result, the failure diagnosis cycle is a cycle that corresponds to nine cycles of the CPU 130 and that corresponds to an operation frequency of 330 Hz.

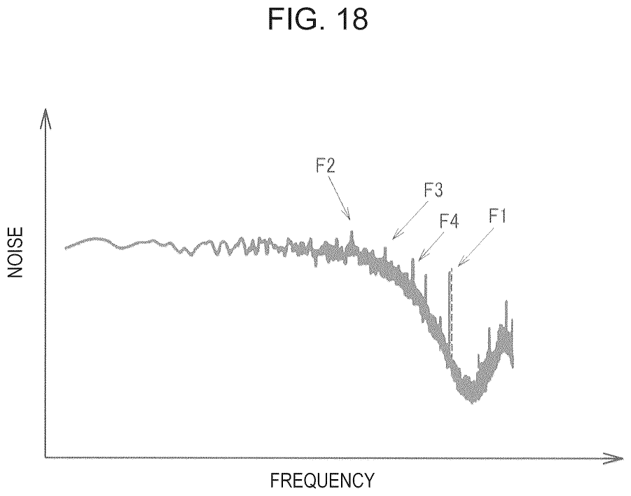

However, in the method of this comparative example, the process regarding the angular velocity is performed at an operation cycle corresponding to a slow frequency of 3 kHz, and there is a problem that the high-speed process cannot be performed. Further, noise with a frequency corresponding to the failure diagnosis cycle is generated, and this noise cannot be sufficiently attenuated by the low-pass filtering process, leading to the problem such as a decrease in detection accuracy. For example, when a pause period occurs during which the failure diagnosis process is not performed, the current consumption during the pause period will be lower than the current consumption during the operating period other than the pause period, thereby generating noise at a frequency corresponding to the failure diagnosis cycle. For example, FIG. 18 shows an example of noise characteristics in a comparative example. The horizontal axis represents a frequency and the vertical axis represents a noise level. F1 in FIG. 18 is noise at a detuned frequency. In FIG. 18, noises indicated by F2, F3, and F4 are generated in addition to the noise at the detuned frequency indicated by F1. These noises have frequencies corresponding to the failure diagnosis cycle. Noise at a frequency of 330 Hz, which corresponds to the failure diagnosis cycle, cannot be sufficiently attenuated by the low-pass filtering process with a cutoff frequency of, for example, about 500 Hz, so that the noise is an unnecessary signal component and reduces the detection accuracy of the physical quantity.

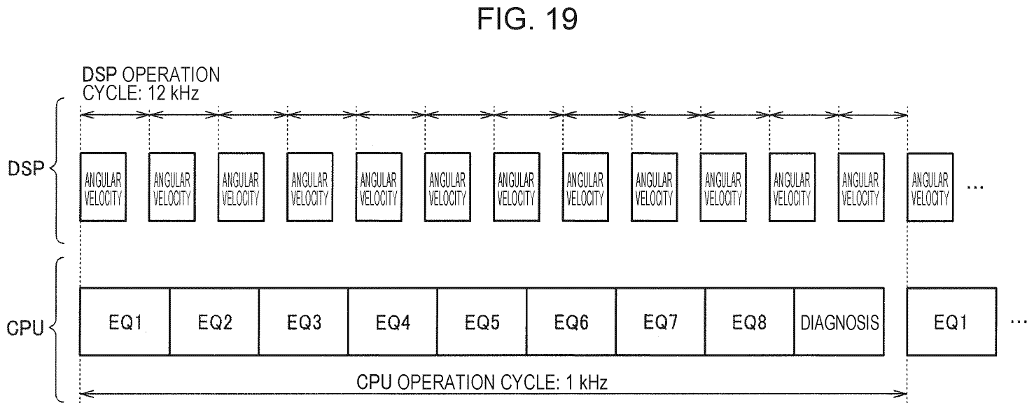

FIG. 19 is an explanatory diagram of the operations of the DSP 100 and CPU 130 in the present embodiment. In FIG. 19, the DSP 100 operates at an operation cycle corresponding to an operation frequency of 12 kHz, and the CPU 130 operates at an operation cycle corresponding to an operation frequency of 1 kHz. 12 kHz, which is the operation frequency of the DSP 100, is a first operation frequency, and 1 kHz, which is the operation frequency of the CPU 130, is a second operation frequency. The second operation frequency is lower than or equal to the first operation frequency. The operating period corresponds to the reciprocal of the operation frequency, for example. The DSP 100 performs a process regarding the angular velocity in each operation cycle corresponding to 12 KHz. For example, the DSP 100 executes the digital signal processes such as the temperature compensation process and the digital filtering process described with reference to FIG. 8 in each operation cycle of FIG. 19.

On the other hand, the CPU 130 executes the failure diagnosis process in an operation cycle corresponding to 1 kHz. For example, the CPU 130 executes the failure diagnosis processes such as EQ1 to EQ8 at an operation cycle of 1 kHz.

In this way, the process regarding the angular velocity can be performed using the DSP 100 at a high-speed operation frequency of 12 kHz. That is, the process regarding the angular velocity can be executed faster than that in the comparative example of FIG. 17, and the detection value of the angular velocity can be output. Further, in the comparative example shown in FIG. 17, since the failure diagnosis cycle corresponds to 330 Hz, a problem arises that the detection accuracy is reduced due to noises indicated by F2, F3, and F3 in FIG. 18. On the other hand, in the present embodiment shown in FIG. 19, the failure diagnosis cycle is a cycle corresponding to 1 kHz, so that even when noise corresponding to the failure diagnosis cycle occurs, the noise can be attenuated by the low-pass filtering process with a cutoff frequency of, for example, about 500 Hz. Therefore, it is possible to prevent the detection accuracy from decreasing due to the failure diagnosis cycle.

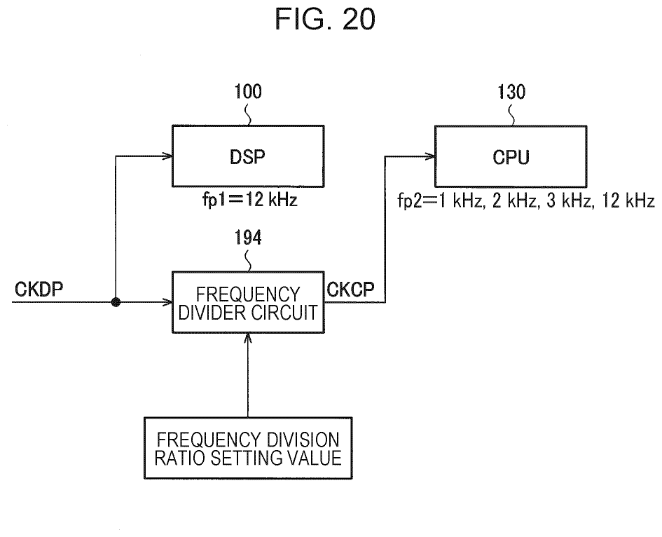

FIG. 20 is an explanatory diagram of the operation frequencies of the DSP 100 and the CPU 130. As shown in FIG. 20, the DSP 100 operates at a first operation frequency fp1. On the other hand, the CPU 130 operates at a second operation frequency fp2. The first operation frequency fp1 of the DSP 100 is, for example, 12 kHz. The second operation frequency fp2 of the CPU 130 is, for example, 1 KHz, 2 kHz, 3 kHz, or 12 kHz, which is lower than the first operation frequency fp1. Further, the second operation frequency fp2 of the CPU 130 is variable, such as 1 kHz, 2 kHz, 3 kHz, or 12 kHz. For example, the DSP 100 operates based on an operating clock signal CKDP, and the CPU 130 operates based on an operating clock signal CKCP. A frequency divider circuit 194 divides the DSP operating clock signal CKDP to output the CPU operating clock signal CKCP. The frequency division ratio of the frequency divider circuit 194 is set by a frequency division ratio setting value. The frequency division ratio setting value is stored, for example, in the nonvolatile memory 164 and the register unit 162 in FIG. 2. In this way, the second operation frequency fp2 of the CPU 130 can be variably set to 1 kHz, 2 kHz, 3 kHz, or 12 kHz by changing the frequency division ratio of the frequency divider circuit 194 using the frequency division ratio setting value. For example, when the CPU 130 performs a large number of processes or when the load of the process performed by the CPU 130 is heavy, the second operation frequency fp2 is set to a high frequency. On the other hand, when the CPU 130 performs a small number of processes or the load of the process performed by the CPU 130 is light, the second operation frequency fp2 is set to a low frequency. This makes it possible to set the second operation frequency fp2 of the CPU 130 to an appropriate frequency according to the number of processes, the processing content, or the processing load of the CPU 130.

Thus, in the present embodiment, the DSP 100 operates at the first operation frequency fp1, and the CPU 130 operates at the second operation frequency fp2 that is lower than the first operation frequency fp1. That is, the DSP 100 operates at a frequency higher than or equal to the operation frequency of the CPU 130, and the CPU 130 operates at a frequency lower than or equal to the operation frequency of the DSP 100. In this way, the process of the physical quantity such as the angular velocity can be executed by the DSP 100 operating at the high first operation frequency fp1. This makes it possible, for example, to output the detection value of the physical quantity with high throughput. On the other hand, the CPU 130 operates at the second operation frequency fp2 that is lower than the first operation frequency fp1 of the DSP 100, so that it is possible to prevent unnecessary power from being consumed in the CPU 130.

Further, the second operation frequency fp2 of the CPU 130 is variable. For example, in FIG. 20, the second operation frequency fp2 is a variable frequency such as 1 KHz, 2 kHz, 3 kHz, or 12 kHz. In this way, for example, while the DSP 100 is operated at the high-speed first operation frequency fp1, the CPU 130 can be operated at the second operation frequency fp2 that is an appropriate frequency depending on the number of processes, the processing content, or the processing load. For example, since the CPU 130 operates programmably based on the program stored in the storage unit 160, it is possible to operate the CPU 130 at the second operation frequency fp2 that is an appropriate frequency according to the process of the program. This makes it possible to provide the circuit device 20 and the physical quantity detection device 5 of various products that are compatible with various processes.

Further, in the present embodiment, when the first operation frequency is fp1, the second operation frequency is fp2, and m is an integer of one or more, the relationship fp2−fp1/m holds true. Taking FIG. 20 as an example, when fp1=12 kHz, by setting m to 12, 6, 4, and 1, fp2 is set to 1 KHz, 2 kHz, 3 kHz, and 12 kHz, respectively. In either case, fp2≤fp1, and fp2 is a variable frequency. In this way, for example, the CPU 130 can operate at the second operation frequency fp2 obtained by dividing the first operation frequency fp1, and the CPU 130 can perform processes with the various number of processes, the processing content, or the processing load. For example, the CPU 130 can operate with the operating clock signal CKCP obtained by frequency-dividing the operating clock signal CKDP of the DSP 100 by the frequency divider circuit 194, and the CPU 130 can execute various processes.

As described above, the circuit device of the present embodiment includes a drive circuit that drives a physical quantity transducer, and a detection circuit that detects a physical quantity based on a detection signal from the physical quantity transducer to output detection data of the physical quantity. The circuit device also includes a DSP that performs a digital signal process including a digital filtering process on detection data, a storage unit that stores a program in which a plurality of instructions is written, and a CPU that operates based on the program and performs at least one of a temperature correction operation of the detection data and a failure diagnosis.

In this way, it is possible to perform a digital signal process including a digital filtering process on the detection data of the physical quantity in the detection circuit using the DSP, and execute a process on the physical quantity. On the other hand, the CPU that operates according to a program stored in the storage unit can perform the temperature correction operation or the failure diagnosis. Therefore, it is possible to achieve a circuit device or the like in which the DSP and the CPU can share and execute the process of the physical quantity and the process of the temperature correction operation or the failure diagnosis.

Further, in the present embodiment, the CPU may obtain the temperature correction value by performing the temperature correction operation based on the temperature data, and the DSP may perform temperature compensation process on the detection data based on the temperature correction value.

In this way, the CPU executes the temperature correction operation, which is a complicated arithmetic process, to be able to obtain an appropriate temperature correction value. On the other hand, the DSP that can operate at high speed executes the temperature compensation process based on the temperature correction value, thereby making it possible to perform the high-speed temperature compensation process on the detection data of the physical quantity.

Furthermore, in the present embodiment, the CPU may perform a comparison process between data generated by the DSP performing the temperature compensation process based on the temperature correction value and data generated by the CPU performing the temperature compensation process based on the temperature correction value, and may perform a failure diagnosis of the DSP and the CPU based on the result of the comparison process.

In this way, by comparing the result of the temperature compensation process by the DSP based on the temperature correction value calculated by the CPU with the result of the temperature compensation process by the CPU based on the temperature correction value calculated by the CPU, the DSP and the CPU can perform the self-failure diagnosis.

Further, in the present embodiment, the CPU may include a fetch circuit that fetches an instruction, an instruction decoder that decodes the fetched instruction, and an arithmetic circuit that performs an arithmetic process based on the decoding result by the instruction decoder.

In this way, the instruction of the program stored in the storage unit can be fetched by the fetch circuit, the fetched instruction can be interpreted by the instruction decoder, and the arithmetic process based on the interpretation result can be executed by the arithmetic circuit.

Further, in the present embodiment, the DSP may perform, as the digital filtering process, the low-pass filtering process in which the cutoff frequency is set according to the drive frequency of the drive circuit.

In this way, the cutoff frequency of the low-pass filtering process can be set to an appropriate cutoff frequency according to the optimal drive frequency of the physical quantity transducer.

Further, in the present embodiment, the DSP may perform, as the digital filtering process, the notch filtering process of attenuating a given frequency component.

In this way, the detection accuracy can be improved by attenuating the frequency component that deteriorates the detection accuracy through the notch filtering process.

Further, in the present embodiment, the DSP may perform, as the digital filtering process, the filtering process whose characteristic is configured to be set via an interface circuit.

In this way, it is possible to cause the DSP to perform the filtering process desired by the user to output the detection value of the physical quantity on which the desired filtering process was performed.

Further, in the present embodiment, the DSP may operate at the first operation frequency, and the CPU may operate at the second operation frequency lower than or equal to the first operation frequency.

In this way, the process of the physical quantity can be executed by the DSP operating at a high first operation frequency. On the other hand, the CPU can be operated at the second operation frequency lower than or equal to the first operation frequency of the DSP.

Further, in the present embodiment, the second operation frequency of the CPU may be variable.

In this way, while the DSP can operate at the high-speed first operation frequency, the CPU can operate at the second operation frequency that is an appropriate frequency depending on the number of processes, the processing content, or the processing load.

Further, in the present embodiment, when the first operation frequency is fp1, the second operation frequency is fp2, and m is an integer of one or more, fp2=fp1/m.

In this way, for example, the CPU can operate at the second operation frequency obtained by dividing the first operation frequency, and the CPU can execute various processes in which the number of processes, the processing content, or the processing load is different.

Further, the physical quantity detection device of the present embodiment may include the circuit device and the physical quantity transducer described above.

Although the present embodiment is described in detail as described above, those skilled in the art will easily understand that many modifications that do not substantially deviate from the new matters and effects of the present disclosure are possible. Therefore, all such modifications are included within the scope of the present disclosure. For example, a term described at least once in a specification or drawing with a broader or synonymous different term may be replaced by that different term anywhere in the specification or drawing. Further, the configurations of the circuit device, physical quantity detection device, physical quantity transducer, and the like are not limited to those described in the present embodiment, and various modifications are possible.

1. A circuit device comprising:
a drive circuit that drives a physical quantity transducer;
a detection circuit that detects a physical quantity based on a detection signal from the physical quantity transducer to output detection data of the physical quantity;
a DSP that performs a digital signal process including a digital filtering process on the detection data;
a storage unit that stores a program in which a plurality of instructions is written; and
a CPU that operates based on the program and performs at least one of a temperature correction operation of the detection data and a failure diagnosis.

2. The circuit device according to claim 1, wherein
the CPU obtains a temperature correction value by performing the temperature correction operation based on temperature data, and wherein
the DSP performs a temperature compensation process on the detection data based on the temperature correction value.

3. The circuit device according to claim 2, wherein
the CPU performs a comparison process between data generated by the DSP performing a temperature compensation process based on the temperature correction value, and data generated by the CPU performing a temperature compensation process based on the temperature correction value, and performs a failure diagnosis of the DSP and the CPU based on a result of the comparison process.

4. The circuit device according to claim 1, wherein
the CPU includes
a fetch circuit that fetches the instruction,
an instruction decoder that decodes the fetched instruction, and
an arithmetic circuit that performs an arithmetic process based on a decoding result by the instruction decoder.

5. The circuit device according to claim 1, wherein
the DSP performs, as the digital filtering process, a low-pass filtering process in which a cutoff frequency is set according to a drive frequency of the drive circuit.

6. The circuit device according to claim 1, wherein
the DSP performs, as the digital filtering process, a notch filtering process of attenuating a given frequency component.

7. The circuit device according to claim 1, wherein
the DSP performs, as the digital filtering process, a filtering process whose characteristic is configured to be set via an interface circuit.

8. The circuit device according to claim 1, wherein
the DSP operates at a first operation frequency, and wherein the CPU operates at a second operation frequency lower than or equal to the first operation frequency.

9. The circuit device according to claim 8, wherein
the second operation frequency of the CPU is variable.

10. The circuit device according to claim 8, wherein
fp2=fp1/m, where fp1 is the first operation frequency, fp2 is the second operation frequency, and m is an integer of one or more.

11. (canceled)

12. A physical quantity detection device comprising:
the circuit device according to claim 1; and
the physical quantity transducer.
